(19) United States
(12) Patent Application Publication
(10) Pub. No.: US 2024/0055306 A1
(43) Pub. Date: Feb. 15, 2024

(54) MANUFACTURING METHOD FOR SILICON CARBIDE SEMICONDUCTOR DEVICE

(71) Applicant: Mitsubishi Electric Corporation, Tokyo (JP)

(72) Inventors: Yuichi NAGAHISA, Tokyo (JP); Shigeto HONDA, Tokyo (JP); Shinya AKAO, Tokyo (JP); Shigehisa YAMAMOTO, Tokyo (JP)

(73) Assignee: Mitsubishi Electric Corporation, Tokyo (JP)

(21) Appl. No.: 18/330,191

(22) Filed: Jun. 6, 2023

(30) Foreign Application Priority Data
Aug. 9, 2022 (JP) 2022-127017

(51) Int. Cl. H01L 21/66; H01L 29/16; H01L 29/06; H01L 29/10; H01L 29/78; H01L 21/02; H01L 21/04; H01L 29/66

(52) U.S. Cl. CPC H01L 22/26; H01L 29/1608; H01L 29/0623; H01L 29/0634; H01L 29/1095; H01L 29/7811; H01L 29/7813; H01L 21/02529; H01L 21/0465; H01L 29/66068

(57) ABSTRACT

The following steps (a) to (d) are provided. The step (a) is to form a drift layer of an n type on a silicon carbide semiconductor substrate of the n type through epitaxial growth. The step (b) is to measure impurity concentration of the drift layer. The step (c) is to form an ion implantation mask on the drift layer, the ion implantation mask including a plurality of first openings being periodically provided. The step (d) is to implant impurity ions of a p type through the plurality of first openings, form a plurality of second pillar regions of the p type in the drift layer, and turn the drift layer between the plurality of second pillar regions into a first pillar region. The step (d) includes performing feedforward control on an ion implantation amount so that there is a positive correlation with measurement results of the step (b).

### BACKGROUND OF THE INVENTION

### Field of the Invention

The present disclosure relates to a manufacturing method for a silicon carbide semiconductor device, and in particular, relates to a manufacturing method for a silicon carbide semiconductor device that can improve a trade-off between a breakdown voltage and on-resistance.

### Description of the Background Art

As semiconductor devices used in power electronics, vertical semiconductor elements including electrodes on both surfaces of a semiconductor substrate are the mainstream, typical examples of which include a metal oxide semiconductor field effect transistor (MOSFET) and an insulated gate bipolar transistor (IGBT). When a regular vertical MOSFET is brought into an OFF state, a depletion layer extends in a drift layer, and this functions as a breakdown voltage holding layer. When thickness of the drift layer is small or impurity concentration of the drift layer is high, only a thin depletion layer can be formed, which leads to reduction of the breakdown voltage of the element. In contrast, when the MOSFET is in an ON state, a main current flows through the semiconductor substrate and the drift layer, and resistance received by the main current is referred to as the on-resistance. The resistance in the drift layer, that is, drift resistance, is higher than resistance of the semiconductor substrate, and is thus one of main resistance components of the MOSFET. Accordingly, by reducing the drift resistance, the on-resistance can be substantially reduced. A typical method therefor includes reducing the thickness of the drift layer or increasing the impurity concentration of the drift layer. For this, there is a trade-off between a high breakdown voltage and low on-resistance.

As a structure that can improve the trade-off between the breakdown voltage and the on-resistance, for example, a super junction structure (SJ structure) as disclosed in WO 2019/069416 A1 is proposed.

The super junction structure refers to a structure in which a pillar of a second conductivity type and a pillar of a first conductivity type are alternately arrayed along a direction perpendicular to a direction of the flow of the main current in the drift layer. According to the structure, in addition to a depletion layer spreading from a pn junction surface or a metal junction surface present near a surface of the semiconductor element, a depletion layer also spreads from the pn junction surface between the pillar of the second conductivity type and the pillar of the first conductivity type. In the SJ structure, in general, both of the pillar of the first conductivity type and the pillar of the second conductivity type are depleted at the time of holding the breakdown voltage, and in this case, an average value of space charge per depth direction is designed to be around 0. This means that termination of a line of electric force due to the space charge per depth direction can be ignored, and this state is referred to as a state of charge balance. Thus, ideally, impurity concentration of the SJ structure can be increased without reducing the breakdown voltage in so far as the pillar of the first conductivity type is depleted, and thus the trade-off between the on-resistance and the breakdown voltage being a problem of the MOSFET can be significantly improved.

In a silicon carbide semiconductor device as well, reduction of the resistance of the drift layer owing to the SJ structure is similarly expected as with the case of the silicon semiconductor device. In contrast, when silicon carbide is used, control of unevenness of impurity concentration poses a problem. In particular, in general, the drift layer required to have low impurity concentration is formed with an epitaxial growth method (hereinafter, epitaxial growth) using the chemical vapor deposition (CVD) method, and the epitaxial growth of the silicon carbide requires high temperature and advanced control on a ratio of a source gas for silicon and carbon, and there is relatively great unevenness of impurity concentration. Thus, drift layer concentration varies for each wafer even if the wafers are epitaxial wafers of the same specification, and there may be unevenness of approximately ±10 to 30% with respect to the center condition, for example. Thus, if the conductivity type of impurities of the drift layer is the first conductivity type, even when the pillar of the second conductivity type can be formed without unevenness, there may be a shift from the charge balance by ±10 to 30%, that is, a charge imbalance, due to the unevenness of the impurity concentration of the drift layer. This may reduce the breakdown voltage in the SJ structure.

Further, regarding the film thickness as well, unevenness in the silicon carbide semiconductor substrate is relatively significant and there may be unevenness of approximately ±5 to 20% with respect to the center condition, although the unevenness is not as much as that of the carrier concentration. When epitaxial growth using a multi-epitaxial method of forming pillar regions through repetitions of epitaxial growth and ion implantation is employed, the unevenness of the film thickness may cause the charge imbalance in a region at the boundary between the epitaxial layers, and may cause reduction of the breakdown voltage.

As described above, in implementation of a silicon carbide MOSFET (SJ-SiC-MOSFET) including an SJ structure, the breakdown voltage is reduced due to the charge imbalance caused by the unevenness of impurity concentration (hereinafter referred to as epitaxial concentration) of the epitaxial layer, and in order to implement the same breakdown voltage, the film thickness needs to be increased accordingly for the epitaxial layer. Therefore, there is a problem in that the on-resistance is reduced.

### SUMMARY

The present disclosure has an object to provide a manufacturing method for a silicon carbide semiconductor device that can reduce a charge imbalance even when there is great unevenness in epitaxial concentration and film thickness of a drift layer among a plurality of wafers.

A manufacturing method for a semiconductor device according to the present disclosure includes the following steps (a) to (f). The step (a) is to form a drift layer of a first conductivity type on a silicon carbide semiconductor substrate of the first conductivity type through epitaxial growth. The step (b) is to measure impurity concentration of the drift layer. The step (c) is to form an ion implantation mask on the drift layer, the ion implantation mask including a plurality of first openings being periodically provided. The step (d) is to implant impurity ions of a second conductivity type through the plurality of first openings, form a plurality of second pillar regions of the second conductivity type in the drift layer, and turn the drift layer between the plurality of second pillar regions into a first pillar region of the first conductivity type. The step (e) is to form an epitaxial layer of the first conductivity type on the drift layer through epitaxial growth. The step (f) is to form a plurality of unit cells of a transistor in the epitaxial layer. The step (d) includes performing feedforward control on an ion implantation amount of the impurity ions so that there is a positive correlation with measurement results of the step (b).

According to the manufacturing method for the semiconductor device according to the present disclosure, the impurity concentration of the drift layer is measured, and the feedforward control is performed on an ion implantation process of forming the second pillar regions so that there is a positive correlation with measurement results. Therefore, a semiconductor device with a reduced charge imbalance can be obtained.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view of a silicon carbide semiconductor device of a first embodiment according to the present disclosure.

FIG. 2 is a partial cross-sectional diagram of the silicon carbide semiconductor device of the first embodiment according to the present disclosure.

FIG. 3 is a partial cross-sectional diagram of the silicon carbide semiconductor device of the first embodiment according to the present disclosure.

FIG. 4 is a partial cross-sectional diagram of the silicon carbide semiconductor device of the first embodiment according to the present disclosure.

FIG. 5 is a partial cross-sectional diagram of the silicon carbide semiconductor device of the first embodiment according to the present disclosure.

FIG. 6 is a flowchart illustrating a method of forming a super junction region of the silicon carbide semiconductor device of the first embodiment according to the present disclosure.

FIG. 7 is a partial cross-sectional diagram illustrating the method of forming the super junction region of the silicon carbide semiconductor device of the first embodiment according to the present disclosure.

FIG. 8 is a partial cross-sectional diagram illustrating the method of forming the super junction region of the silicon carbide semiconductor device of the first embodiment according to the present disclosure.

FIG. 9 is a partial cross-sectional diagram illustrating the method of forming the super junction region of the silicon carbide semiconductor device of the first embodiment according to the present disclosure.

FIG. 10 is a partial cross-sectional diagram illustrating the method of forming the super junction region of the silicon carbide semiconductor device of the first embodiment according to the present disclosure.

FIG. 11 is a flowchart illustrating a method of forming a super junction region of the silicon carbide semiconductor device of the first embodiment according to the present disclosure.

FIG. 12 is a graph showing a method of forming a pillar region in a uniform depth direction profile.

FIG. 13 is a flowchart illustrating a method of forming a super junction region of the silicon carbide semiconductor device of the first embodiment according to the present disclosure.

FIG. 14 is a graph showing a method of forming a pillar region in a uniform depth direction profile.

FIG. 15 is a cross-sectional diagram of the super junction region when a multi-epitaxial method is repeated four times.

FIG. 16 is a graph showing a profile of impurity concentration of acceptor ions and donor ions in the depth direction in the super junction region when the multi-epitaxial method is repeated four times.

FIG. 17 is a cross-sectional diagram illustrating an optimal design of the super junction region using a pn diode structure.

FIG. 18 is a graph showing a relationship between a pillar pitch, on-resistance, and impurity concentration.

FIG. 19 is a diagram illustrating a state at the time of holding a breakdown voltage when a charge balance is satisfied.

FIG. 20 is a graph showing electric field distributions of an n-type pillar and a p-type pillar when the p-type pillar and the n-type pillar are fully depleted.

FIG. 21 is a graph showing electric field distributions of the n-type pillar and the p-type pillar when impurity concentration of a p-type region varies in the pn diode structure.

FIG. 22 is a graph showing electric field distributions of the n-type pillar and the p-type pillar when impurity concentration of an n-type region varies in the pn diode structure.

FIG. 23 is a graph showing a profile of impurity concentration of the super junction region at a certain depth.

FIG. 24 is a table showing table data of an implantation amount when unevenness of impurity concentration and unevenness of an opening width of a resist are fed forward.

FIG. 25 is a graph showing a method of feeding film thickness of a drift layer forward to the implantation amount and implantation energy.

FIG. 26 is a plan view of a silicon carbide semiconductor device of a second embodiment according to the present disclosure.

FIG. 27 is a partial cross-sectional diagram of the silicon carbide semiconductor device of the second embodiment according to the present disclosure.

FIG. 28 is a partial cross-sectional diagram of a silicon carbide semiconductor device of a third embodiment according to the present disclosure.

FIG. 29 is a partial cross-sectional diagram of a modification of the silicon carbide semiconductor device of the third embodiment according to the present disclosure.

### DESCRIPTION OF THE PREFERRED EMBODIMENTS

### Introduction

Embodiments according to the present disclosure will be described below with reference to the drawings. Note that the drawings are schematically illustrated, and dimensions of each constituent element in the drawings in the horizontal direction and the vertical direction are not accurate illustrations of actual dimensions, and dimension ratios are not accurate. Further, in the following description, similar constituent elements are denoted by the same reference signs in the illustrations, and also have similar terms and functions. Thus, detailed description thereof may be omitted in some cases.

Further, in the following description, terms indicating specific positions and directions, such as “up”, “down”, “side”, “front”, or “back”, may be used. These terms are used for the sake of convenience in order to facilitate understanding of details of the embodiments, and are not related to directions in actual implementation.

Further, in the following description, an “outer side” refers to a direction toward an outer periphery of a semiconductor substrate, and an “inner side” refers to a direction opposite to the “outer side”.

In the present disclosure, description will be given by taking an example of a silicon carbide (SiC) semiconductor device as a semiconductor device, and taking, in particular, an example of an n-channel silicon carbide MOSFET in which a first conductivity type is an n type and a second conductivity type is a p type. Description regarding highs and lows of potentials is description for a case in which the n type is the first conductivity type and the p type is the second conductivity type. For a case in which the n type is the second conductivity type and the p type is the first conductivity type, opposite description regarding highs and lows of potentials applies. In addition, of the entire semiconductor device, a region in which a unit cell is periodically disposed is referred to as an active region, and a region on an outer peripheral side thereof is referred to as an outer peripheral region.

### First Embodiment

### Device Configuration

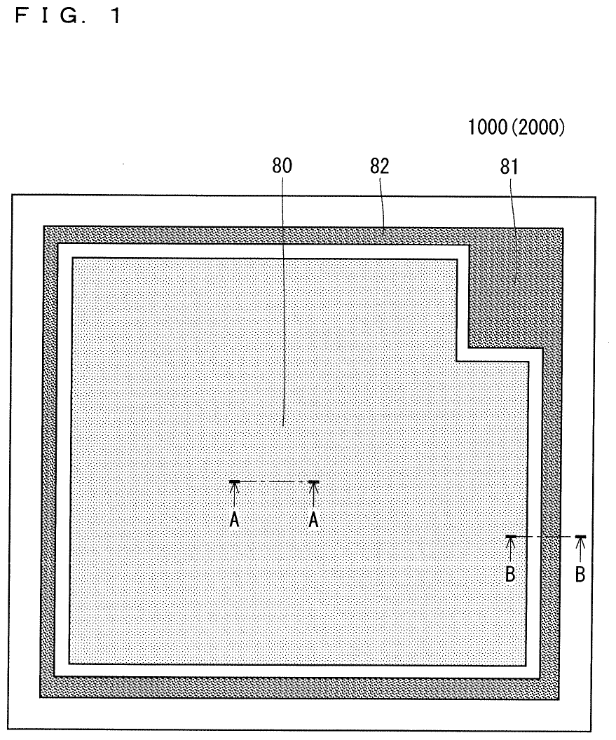

FIG. 1 is a plan view in which an SJ-SiC-MOSFET 1000 being a silicon carbide semiconductor device of a first embodiment according to the present disclosure is seen from a source electrode side being an upper surface. Note that FIG. 1 is also used as a plan view of an SJ-SiC-MOSFET 2000 of a second embodiment to be described later.

As illustrated in FIG. 1, the SJ-SiC-MOSFET 1000 is a semiconductor chip having a rectangular shape in plan view, in which a gate wiring 82 is provided to surround outer periphery of a source electrode 80 occupying a most part of the semiconductor chip, and the gate wiring 82 extends from a gate pad 81 provided at a corner of the semiconductor chip. The gate pad 81 and the gate wiring 82 can be formed of the same conductor.

Note that dispositions and shapes of the source electrode 80, the gate pad 81, and the gate wiring 82 are merely examples, and are not limited to those of FIG. 1.

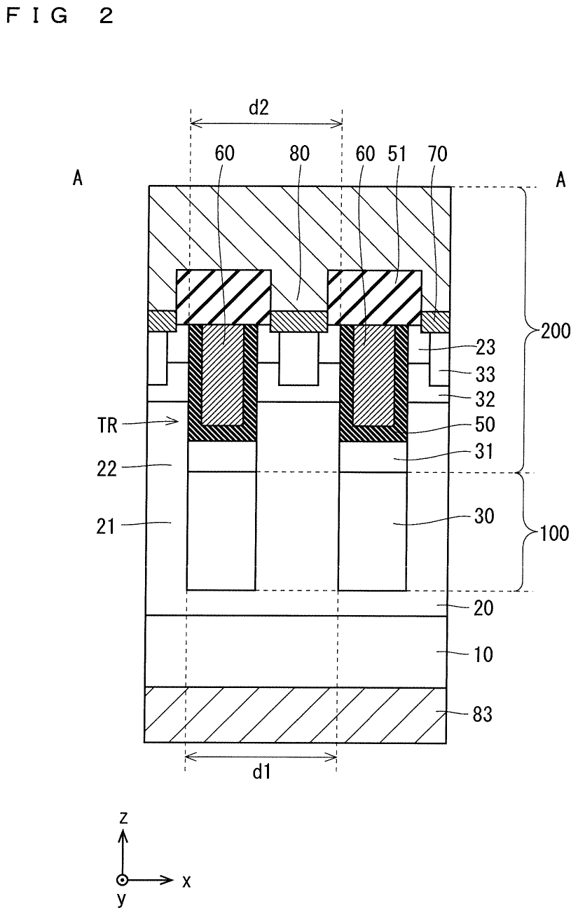

FIG. 2 is a cross-sectional diagram taken along the line A-A of FIG. 1 as seen in the direction of the arrows, and illustrates a configuration of a unit cell periodically and repeatedly disposed in a region below the source electrode 80. In the present embodiment, as an example, a trench MOSFET structure being a general structure of an SJ-SiC-MOSFET will be described.

In the SJ-SiC-MOSFET 1000 of the first embodiment, a p-type electric field protection region 31 is provided below a trench gate TR, and a p-type pillar region 30 (second pillar region) is provided below the p-type electric field protection region 31.

In other words, as illustrated in FIG. 2, in the SJ-SiC-MOSFET 1000, an n-type drift layer 20 is provided on a first main surface of an n-type silicon carbide semiconductor substrate 10. In the drift layer 20, the p-type pillar region 30 formed with an ion implantation method and activation annealing is provided. Further, an n-type region in the drift layer 20 in which the pillar region 30 is not formed is referred to as a pillar region 21 (first pillar region). Impurity concentration of the pillar region 21 may be the same as that of the drift layer 20; however, in order to maximize effects of the SJ structure, the impurity concentration of the pillar region 21 may be higher impurity concentration with an additional epitaxial growth process, ion implantation process, or the like.

As illustrated in FIG. 2, a region in which the pillar region 21 and the pillar region 30 are repeatedly arrayed in the horizontal direction in the drawing sheet, that is, in an array direction (x direction) of the trench gates TR, with a repetition period d1 is referred to as an SJ region 100. The repetition period d1 may be referred to as a pillar pitch d1. In the SJ region 100, the pillar region 21 and the pillar region 30 are formed along the depth direction in the drawing sheet in plan view, that is, in an extension direction (y direction) of each trench gate TR, and is formed to have a stripe shape in plan view.

Further, a region above the SJ region 100 is referred to as a MOSFET region 200, and the pillar region 30 is connected to a p-type impurity region in the MOSFET region 200. In a case of the trench structure, the pillar region 30 can be formed to be connected to the p-type electric field protection region 31.

In the MOSFET region 200, the trench gates TR formed to reach into the drift layer 20 from an outermost surface of the drift layer 20 are provided. Regarding each trench gate TR, a gate insulation film 50 formed of silicon oxide or the like having a thickness of 25 to 150 nm is formed to cover an inner surface of the trench formed by digging into the drift layer 20, and a gate electrode 60 formed of polycrystalline silicon or the like is formed to fill a region surrounded by the gate insulation film 50. The trench gates TR are repeatedly provided with a repetition period d2, and the top of each gate electrode 60 is covered by an interlayer insulation film 51 formed of silicon oxide or the like.

In an upper layer portion of the drift layer 20, an n-type source region 23 provided between the trench gates TR is selectively provided, and a p-type body region 32 is provided below the source region 23. Inside the source region 23 and the body region 32, a p-type body contact region 33 is provided. The body contact region 33 is provided to penetrate the source region 23 but not to penetrate the body region 32.

An ohmic electrode 70 is provided above the body contact region 33, and the ohmic electrode 70 is connected to the source electrode 80 through an opening provided between the interlayer insulation films 51.

The pillar region 21 below the body region 32 and between the trench gate TR and the electric field protection region 31 is referred to as a JFET region 22. Since impurity concentration of the JFET region 22 is not required to have a charge balance, unlike that of the SJ region 100, the impurity concentration may be higher than that of the pillar region 21, so that JFET resistance is reduced. In contrast, in order to reduce manufacturing processes, the impurity concentration of the JFET region 22 may be the same as the concentration of the pillar region 21, that is, the drift layer 20 being an epitaxial layer may be directly used.

The electric field protection region 31 provided at a bottom portion of the trench gate TR is connected to the body region 32 in an unillustrated part in the depth direction in the drawing sheet in plan view, and has a source potential. With this, the pillar region 30 connected to the electric field protection region 31 has a fixed potential, and can thus stabilize the potential of the pillar region 30.

Impurity concentration of the electric field protection region 31 is preferably higher than that of the pillar region 30; however, the impurity concentration of the electric field protection region 31 may be the same as the impurity concentration of the pillar region 30, or may be lower than the impurity concentration of the pillar region 30.

The impurity concentrations of the pillar region 21 and the pillar region 30 may vary due to unevenness of processes or the like, but are designed to largely have a charge balance in general. The charge balance refers to a condition in which the sum of space charge densities when the pillar region 21 and the pillar region 30 are fully depleted at the same depth (certain depth in the z direction) is close to zero, with positive and negative values cancelling each other out. Specifically, this can be implemented by designing the SJ region 100 such that the product of a pillar width of the pillar region 21 and the impurity concentration of the pillar region 21 and the product of a pillar width of the pillar region 30 and the impurity concentration of the pillar region 30 are substantially equal to each other.

As a matter of course, as a design range, a ratio of total depletion layer charges at the time of full depletion at a certain depth, that is, a degree of the charge balance, can be changed. For example, when a total number of depletion layer charges ionized by the pillar region 21 is represented by Nntot and a total number of depletion layer charges ionized by the pillar region 30 is represented by Nptot, a value of a ratio of total depletion layer charges defined by Nntot/Nptot can be changed by approximately 0.5 to 2.0. A case in which the value of Nntot/Nptot is 1 is a state of a charge balance, a case in which the value is larger than 1 and 2.0 or less is referred to as a “positive side”, and a case in which the value is 0.5 or higher and less than 1 is referred to as a “negative side”.

When the ratio of the total depletion layer charges is on the positive side, characteristics closer to an n-type MOSFET are exhibited, and thus a small amount of carriers as a cause of a reverse recovery current of a body diode of the MOSFET can be reduced. Alternatively, when the ratio is on the negative side, portions where electrical breakdown occurs can be shifted to the inner side with respect to a substrate surface, and by extending an energization path of an avalanche current, the avalanche current can be reduced and avalanche tolerance can be enhanced.

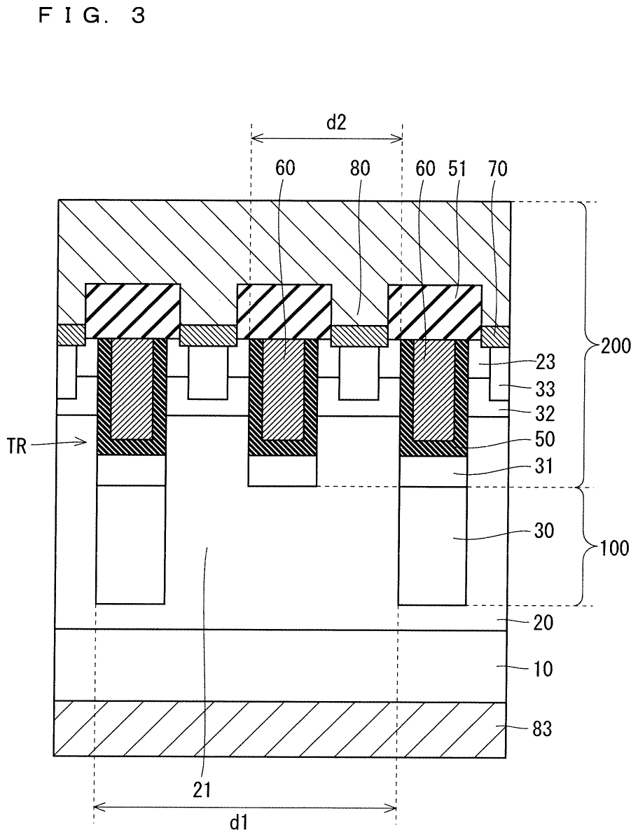

The SJ-SiC-MOSFET 1000 illustrated in FIG. 2 illustrates a configuration in which the repetition period d1 of the pillar region 21 and the pillar region 30 in the SJ region 100 and the repetition period d2 of the trench gates TR in the MOSFET region 200 match each other, but both of them need not necessarily match each other. For example, as illustrated in FIG. 3, the repetition period d1 can be an integer multiple of the repetition period d2. In this case, spread resistance occurring as a result of spread of the width of the pillar region 21 and no smooth spread of a main current path due to a depletion layer extending from the pillar region 30 can be reduced.

In other words, even in an ON state, a diffusion potential and a potential difference of a voltage drop in the pillar region 21 are applied to a pn junction between the pillar region 30 and the pillar region 21, and the depletion layer spreads depending on a value thereof. The spread depletion layer obstructs the main current path and prevents the main current path from smoothly spreading, and thus resistance of the main current path increases. In contrast, when the width of the pillar region 21 spreads, the main current path below the trench gate TR spreads, and thus resistance of the main current path in the SJ region 100 reduces.

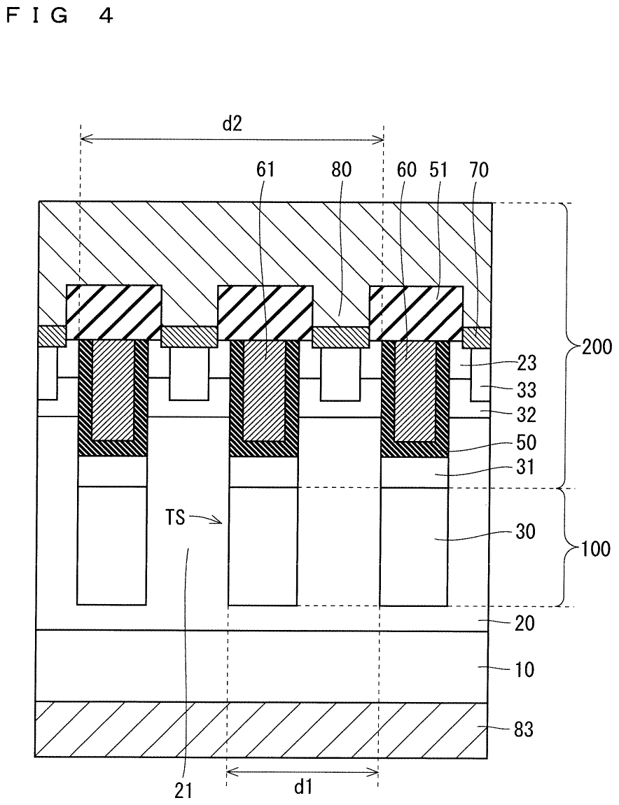

Similarly, the repetition period d2 need not match the repetition period d1 either. For example, as illustrated in FIG. 4, by employing a configuration in which a trench source TS is disposed between the trench gates TR in the MOSFET region 200, the number of trench gates TR can be reduced, and a configuration with reduced input capacity can be achieved.

The trench source TS is a configuration similar to the trench gate TR, and the gate insulation film 50 is formed to cover an inner surface of the trench formed by digging into the drift layer 20, and a trench source electrode 61 formed of polycrystalline silicon or the like is formed to fill a region surrounded by the gate insulation film 50. The trench source electrode 61 is connected to the source electrode 80 in an unillustrated part in the depth direction in the drawing sheet in plan view, and does not function as a gate electrode.

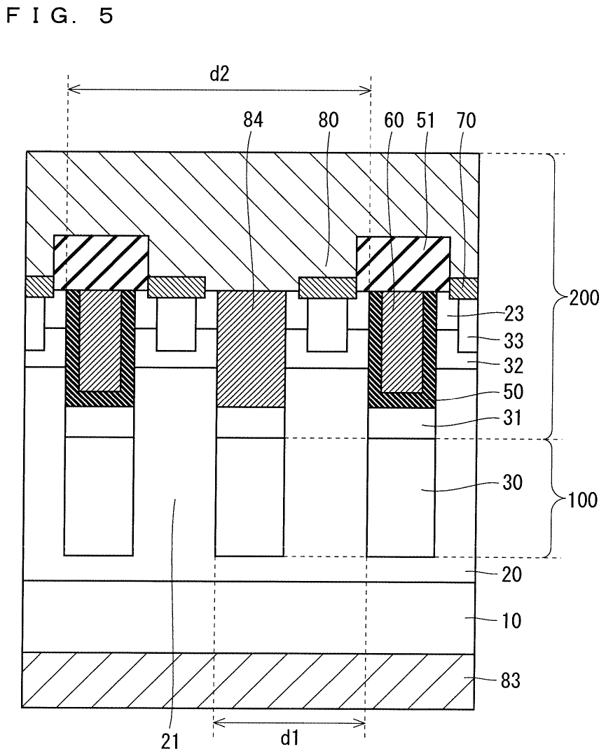

Further, as illustrated in FIG. 5, by employing a configuration in which a trench Schottky electrode 84 is disposed between the trench gates TR, a MOSFET embedded with a Schottky barrier diode (SBD) can be achieved. The trench Schottky electrode 84 is provided to fill the trench formed by digging into the drift layer 20, and is in contact with the source electrode 80. According to the configuration, energization of a bipolar current at the time of reverse operation can be reduced, and increase of an on-voltage and increase of a leakage current due to crystal defects specific to SiC can be reduced.

### Manufacturing Method

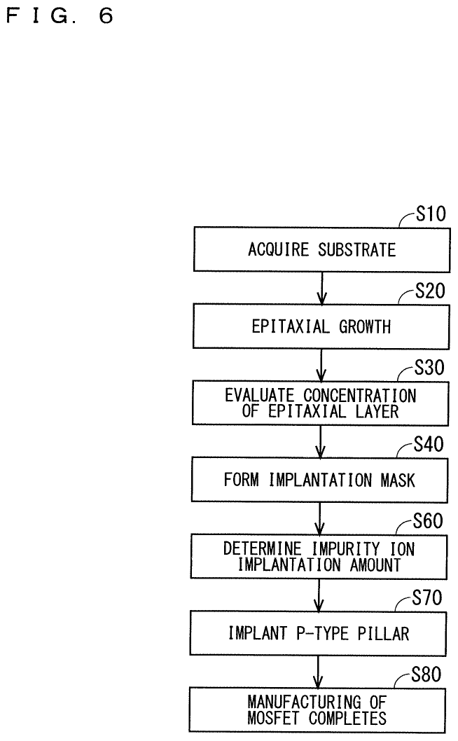

Next, a manufacturing method for the SJ-SiC-MOSFET 1000 of the first embodiment will be described. The manufacturing method for the silicon carbide semiconductor device according to the present disclosure essentially requires application of a multi-epitaxial method in which the SJ structure is formed by repeating a process of forming the n-type drift layer 20 with epitaxial growth and forming the p-type pillar region 30 with ion implantation at least one time. A method of forming the SJ region 100 using the multi-epitaxial method will be described below with reference to the flowchart illustrated in FIG. 6.

FIG. 6 is a flowchart illustrating a manufacturing process including an ion implantation process in which feedforward is carried out, which is characteristic of the manufacturing method for the silicon carbide semiconductor device according to the present disclosure. Note that FIG. 6 explicitly illustrates only processes important for the sake of description of effects of the implantation process using feedforward, and various processes, that is, cleaning, external appearance inspection, and the like, are carried out between the processes.

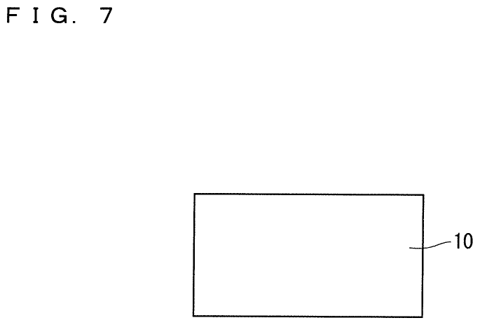

As illustrated in FIG. 6, first, the silicon carbide semiconductor substrate 10 in a wafer state is acquired (Step S10), and subsequently, substrate cleaning and the like are carried out to make the silicon carbide semiconductor substrate 10 in a clean state. The state is illustrated in FIG. 7. Subsequently, on the silicon carbide semiconductor substrate 10, an n-type epitaxial layer is formed to have a thickness of several hundreds of nanometers to several tens of micrometers with epitaxial growth using the CVD method, so as to form the drift layer 20 (Step S20).

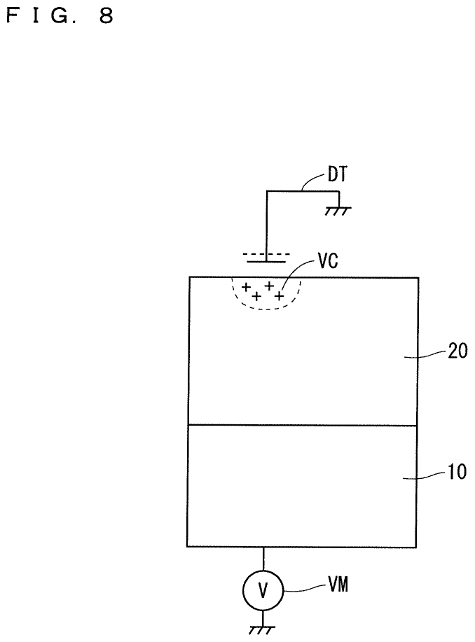

Subsequently, average impurity concentration per wafer is determined with CV measurement or the like, and concentration of the epitaxial layer is evaluated (Step S30). FIG. 8 schematically illustrates a state in which a voltmeter VM is connected to a back surface of the silicon carbide semiconductor substrate 10 and a probe DT of a CV measurement device is disposed on an upper surface of the drift layer 20, so as to measure carrier concentration of a depletion layer VC within the surface of the drift layer 20.

Carrier concentration of an epitaxial layer of a general silicon carbide semiconductor substrate is, for example, acquired by measuring electrostatic capacity at each of a plurality of points within a surface of the silicon carbide semiconductor substrate and calculating the carrier concentration for each measurement point from an electrostatic capacity value, with use of a CV measurement device including a mercury probe. The carrier concentration for each measurement point is averaged, and average carrier concentration within the surface of the silicon carbide semiconductor substrate 10 is then evaluated.

When there is only one repetition of epitaxial growth and ion implantation, a commercially available silicon carbide semiconductor substrate in which an epitaxial layer of known concentration is grown can also be used. In that case, an epitaxial growth process can be omitted, and therefore production facilities can be simplified.

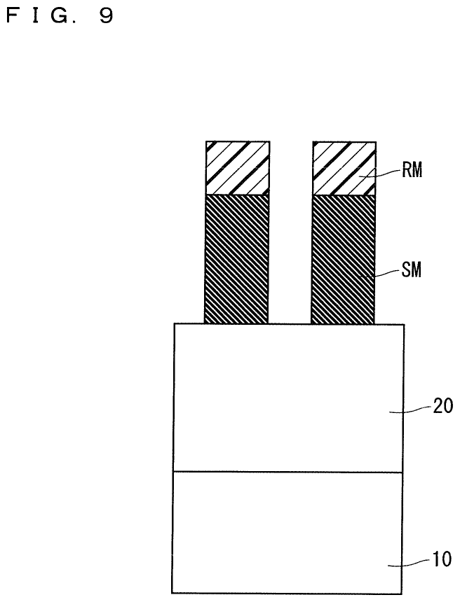

Subsequently, a silicon oxide (SiO₂) film is formed on the drift layer 20, a resist material is applied onto the silicon oxide film, and the resist material is patterned with photolithography so as to form a resist mask RM as illustrated in FIG. 9, and the silicon oxide film is patterned with dry etching using the resist mask RM so as to form an implantation mask SM for ion implantation (Step S40). Note that the implantation mask SM made of silicon oxide has high selectivity with silicon carbide, and thus the drift layer 20 can be etched without being removed. Note that the material is not necessarily limited to SiO₂ as long as the material has high selectivity with silicon carbide and is a chemically stable material.

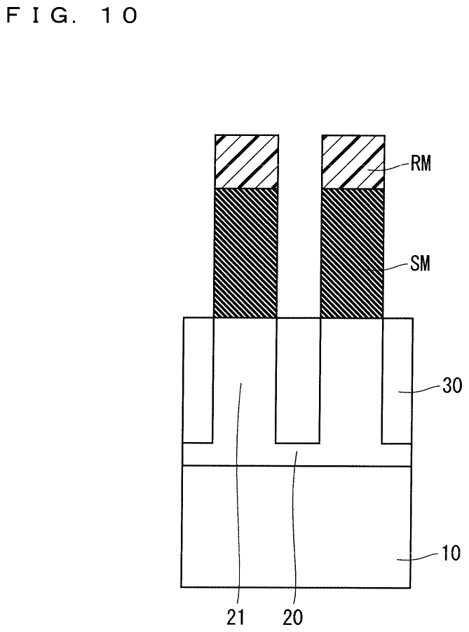

After the implantation mask SM is formed, an implantation amount of impurity ions is determined (Step S60), p-type impurity ion implantation is performed using the implantation mask SM for ion implantation (Step S70), and the pillar region 30 is formed in the drift layer 20 as illustrated in FIG. 10. After the pillar region 30 is formed, a MOSFET manufacturing process of related art is performed, and as a result, the SJ-SiC-MOSFET 1000 is completed (Step S80).

### Feedforward to Implantation Amount

In the following, determination of the implantation amount of impurity ions in Step S60 will be further described. First, the average impurity concentration per wafer of the drift layer 20 is acquired in Step S30, and thus the implantation amount of impurity ions is determined based on the value. Specifically, the implantation amount is determined to minimize a total charge imbalance formed within the surface of the drift layer 20.

For example, when the average impurity concentration per wafer of the drift layer 20 is fluctuated by ±15% with respect to the design center, by similarly changing the ion implantation amount with a fluctuation of ±15% as well, the charge imbalance can be reduced within a range without unevenness of the ion implantation process, unevenness of the implantation mask, and unevenness of epitaxial concentration within the wafer surface. In other words, control is performed so that the implantation amount and concentration of the epitaxial layer have a positive correlation. In general, the ion implantation process has a small unevenness, and in addition, SiC has significantly small thermal diffusivity of implanted ions, and thus the implantation process with SiC has a significantly small unevenness. By feeding the results of the epitaxial growth process having a large unevenness forward to the implantation process, the charge imbalance within the wafer surface can be significantly reduced.

Further, regarding the change of the implantation amount, in addition to changing the value every time within a predetermined range, for example, work efficiency can be enhanced with a method in which work recipes in which an implantation condition of simplified Level 2 or higher are prepared in advance, and a work recipe is selected depending on average epitaxial concentration of the wafer.

In other words, when an n-type transistor is assumed, the essence of the present disclosure lies in adjusting an acceptor ion implantation amount in proportion to the unevenness of the epitaxial concentration and maintaining the charge balance amount to a fixed value to the extent possible. For example, when the epitaxial concentration increases by 10% due to unevenness, the dosage of acceptor ions is similarly increased by 10%, so that there is a positive correlation.

Accordingly, simplification to Level 2 means preparation of the implantation condition of Level 2 for a management width of the epitaxial concentration that may vary in a production process. Specifically, when an epitaxial layer production method in which there is unevenness of ±20% with respect to the center condition is used, a region in 20% on a high concentration side from the center, that is, a region with concentration having 20% higher than the average, is provided, a region in 20% on a low concentration side from the center, that is, a region with concentration having 20% lower than the average, is provided, and the implantation amount of acceptor ions is determined so that the charge balance amount is fixed with respect to the center of each region. In this case, when the epitaxial concentration results in being higher than a process center, the implantation amount of acceptor ions is increased by 10%, and when the epitaxial concentration results in being lower, the implantation amount of acceptor ions is reduced by 10%.

Note that, instead of setting the implantation condition individually for each single wafer, by reducing arbitrariness of the implantation condition and performing treatment in a simplified process, such as by using condition A for a wafer having high concentration and using condition B for a wafer having low concentration, the manufacturing process can be simplified. Note that a specific feedforward method for the implantation amount will be described later.

### Feedforward with Opening Width of Implantation Mask

As a parameter to be fed forward to the implantation amount of impurities, not only the epitaxial concentration but also the opening width of the implantation mask can be fed forward. For example, when the opening width is increased, the amount of impurities to be supplied to a certain depth is increased even with the same implantation amount, and thus in order to maintain an optimal charge balance, the implantation amount needs to be adjusted.

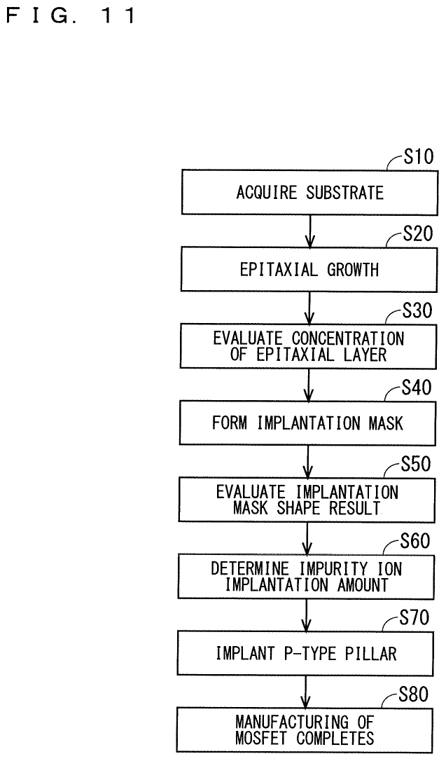

FIG. 11 is a flowchart illustrating a manufacturing process in which a process of evaluating the opening width of the implantation mask is included before determining the implantation amount of impurity ions. In FIG. 11, before Step S60 of determining the implantation amount of impurity ions, implantation mask shape result evaluation (Step S50) of evaluating the opening width of the implantation mask is introduced.

In this case, the implantation amount can be determined to have a negative correlation with the average value within the wafer surface of the measured opening width. Further, in order to enhance work efficiency, the implantation condition can be prepared in advance as a discrete condition of Level 2 or higher.

Here, the discrete implantation condition of Level 2 or higher refers to an implantation condition in which, when the resist opening width varies by ±20% with respect to the design center, the dosage is decreased by 10% for the opening width having a designed value or higher, and the dosage is increased by 10% for the opening width having less than the designed value.

A set value of the dosage can be set so that there is a negative correlation with the opening width, similarly to the feedforward to the unevenness of the epitaxial concentration. For example, when the opening width is larger than the design center, the dosage may be decreased by 7%, or otherwise the dosage may be increased by 7%. Note that the absolute value of the feedforward amount when the opening width fluctuates and shifts from the design center may not necessarily be the same. For example, when the opening width is larger than the design center, the dosage may be decreased by 9%, or otherwise the dosage may be increased by 5%.

Such setting may be changed depending on how the result of the opening width distributes with respect to the design center, that is, whether the distribution is regular distribution, whether the distribution is uniform distribution with a certain probability, whether the distribution is symmetrical with respect to the design center, or the like. A specific feedforward method for the implantation amount will be described later.

### Pillar Implantation

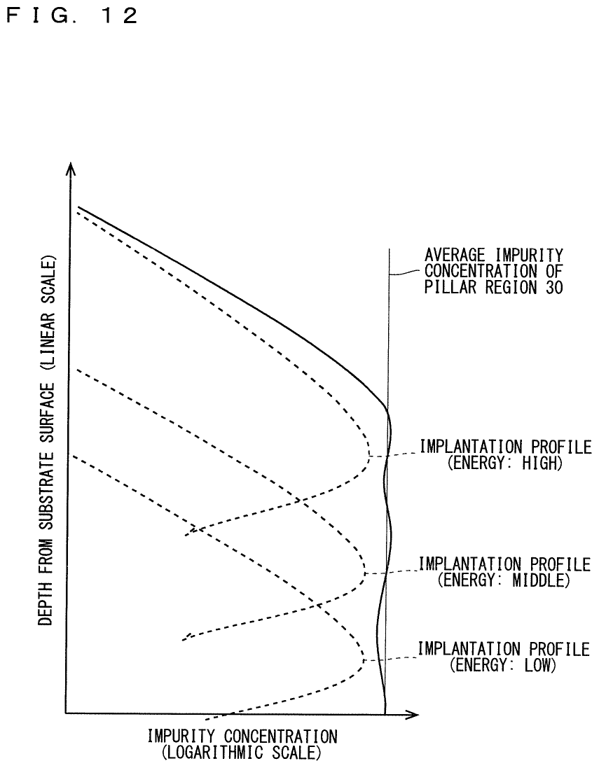

In ion implantation to the pillar region, that is, p-type pillar implantation (Step S70) of FIG. 6 and FIG. 11, the pillar region 30 is formed so as to achieve a uniform depth direction profile by changing the implantation energy and the dosage with implantation energy not penetrating a photoresist and a mask for ion implantation, that is, implantation energy of several hundreds of kilo electron volts to several mega electron volts or less dependent upon the thickness of the mask for ion implantation. A specific example thereof is shown in FIG. 12.

FIG. 12 is an implantation profile in which the horizontal axis indicates the impurity concentration on a logarithmic scale and the vertical axis indicates the depth from the substrate surface on a linear scale.

As shown in FIG. 12, for example, by setting the implantation energy to three stages of low, middle, and high, the concentration forms a uniform pillar region 30. In this specification, ion implantations to be fed forward is all of these implantations, and there is a purpose of controlling the impurity concentration of the pillar region 30 obtained as a result of the plurality of stages of ion implantations. Examples of p-type implanted elements used for ion implantation include boron (B) and aluminum (Al).

### Multi-Epitaxial Method

The formation process of the epitaxial layer illustrated in FIG. 7 to FIG. 10 illustrates a case in which there is only one repetition of epitaxial growth and ion implantation. However, in the multi-epitaxial method in which repetitions of epitaxial growth and ion implantation are repeated a plurality of times, the pillar region 30 is formed, then the resist mask RM and the implantation mask SM are removed, an n-type epitaxial layer is formed again, epitaxial concentration is evaluated, the processes of Step S40 and the following steps of FIG. 6 or FIG. 11 are performed, and as a result, the pillar region 30 is extended in the vertical direction. These processes are repeated a plurality of times, and the SJ region 100 including the pillar region 21 and the pillar region 30 is thereby formed. By carrying out implantation with feedforward for each repeated process, the SJ structure with a minimized charge imbalance can be implemented.

In the multi-epitaxial method, feedforward of implantation energy for a film thickness of the epitaxial layer (hereinafter referred to as an epitaxial film thickness) may be added.

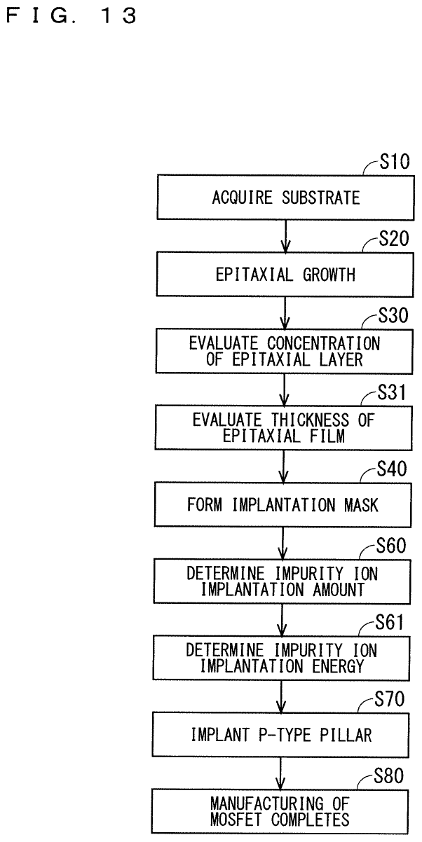

FIG. 13 is a flowchart in which a process of evaluating the epitaxial film thickness is added after evaluating the concentration of the epitaxial layer, and a process of determining the implantation energy for impurity ions is added after determining the implantation amount of impurity ions. In FIG. 13, Step S31 of evaluating the epitaxial film thickness is introduced after Step S30 of evaluating concentration of the epitaxial layer, and Step S61 of determining the implantation energy for impurity ions is inserted after Step S60 of determining the implantation amount of impurity ions.

To evaluate the epitaxial film thickness, as an example, the following method or the like is carried out: the epitaxial film thickness at a plurality of points within the wafer surface is measured with a Fourier-transform infrared spectroscopy (FTIR) or the like, and average film thickness is calculated.

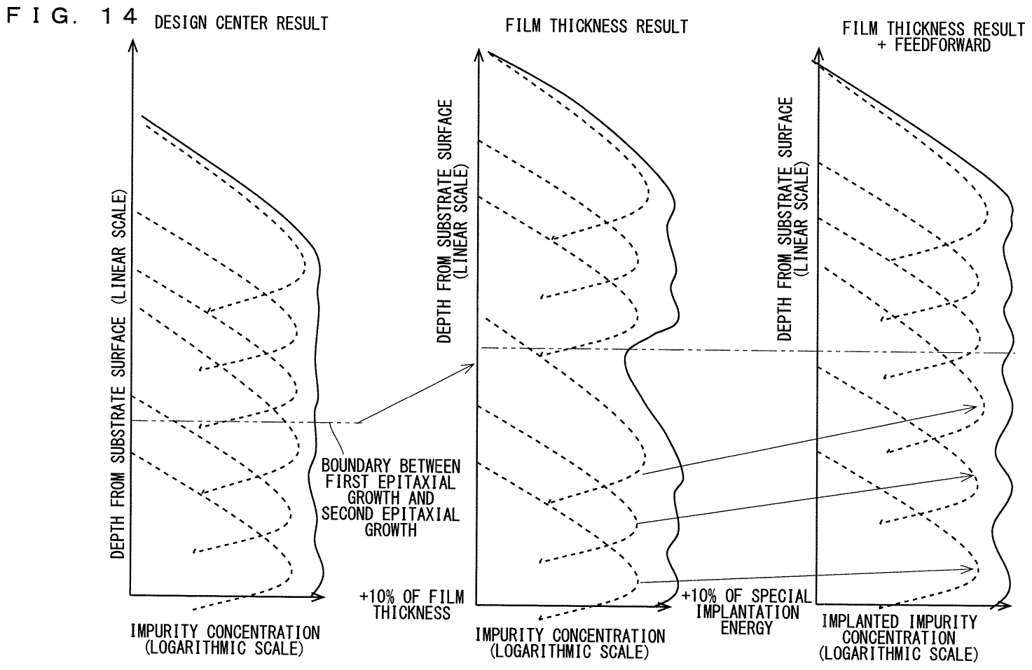

In this case, energy of each implantation at the time of carrying out multi-stage implantation can be adjusted so that there is a positive correlation with the epitaxial film thickness. When the film thickness is unintentionally increased, connection of the pillar region 30 can be prevented from being weakened between the epitaxial layers by multiplying the implantation energy of each stage certain times. A specific example thereof is shown in FIG. 14.

In FIG. 14, the horizontal axis indicates the impurity concentration on a logarithmic scale, and the vertical axis indicates implantation profiles in which the depth from the substrate surface is shown on a linear scale. The vertical axis specifically indicates three implantation profiles of a case of “design center result” in which the film thickness results in the same thickness as the designed value, a case of “film thickness result” in which the epitaxial film thickness results in an unintentional thickness, and a case of “film thickness result+feedforward” with feedforward to the implantation energy when the epitaxial film thickness results in an unintentional thickness.

In any of the implantation profiles in FIG. 14 shows a case in which epitaxial growth is performed two times and ion implantation is performed with the three-stage implantation energy for each epitaxial layer, and indicates a boundary between the first epitaxial growth and the second epitaxial growth with a chain line.

When the film thickness results in a thickness 10% higher than the design center, as shown in the implantation profile of “film thickness result”, a region with locally reduced concentration of the pillar region 30 is generated near the boundary between the epitaxial growths. Thus, when the charge imbalance is locally generated in the region and resistance of the pillar region 21 is increased, a breakdown voltage and a switching speed are reduced. In contrast, when each implantation energy is increased by 10% in response to increase of the film thickness, implantation depth being at the center is also increased substantially by 10%, and thus as shown in the implantation profile of “film thickness result+feedforward” of FIG. 14, the profile of the pillar region 30 can be made uniform and the above-described problems can be alleviated.

In contrast, when the film thickness is reduced, a region with locally high impurity concentration is generated in the pillar region 30, and the breakdown voltage is reduced due to generation of the charge imbalance. In this case as well, similarly, by reducing the implantation energy lower than the design center, reduction of the breakdown voltage can be resolved.

In conclusion, by controlling the implantation energy so that there is a positive correlation with the epitaxial film thickness, occurrence of problems caused due to increase and decrease of the epitaxial film thickness can be reduced. The method of changing the implantation energy also accepts a continuous change, and a selection can be made among discrete conditions of Level 2 or higher set in advance similarly to the implantation amount.

Although the above describes the multi-epitaxial method in which p-type impurity ions are implanted into the n-type epitaxial layer, the n type and the p type are interchangeable. Further, the epitaxial layer may be set as a region with low impurity concentration, and an n-type region may be formed with ion implantation being performed on the entire surface thereof. When the n-type region is formed, impurities of nitrogen (N) or phosphorus (P) are implanted in general.

### Costs of Multi-Epitaxial Method and Device Performance

In the multi-epitaxial method, manufacturing costs are mainly dependent upon the number of multi-epitaxial growths. In contrast, when the number of multi-epitaxial growths is to be reduced, a special process, such as MeV ion implantation, is required. Thus, for example, there is a tendency that performance of the semiconductor device is reduced, such as by increase of implantation defects due to increase of the implantation energy and increase of working dimensions due to increase of film thickness of the mask for implantation. Note that, although details will be described later, in the SJ-MOSFET, in general, advanced microfabrication leads to a high aspect ratio and high concentration, and a reduced repetition period leads to enhancement of performance, that is, reduced on-resistance at the same breakdown voltage. Thus, in the multi-epitaxial method, there is a trade-off between the manufacturing costs and the device performance, and the balance therebetween is determined mainly by the number of multi-epitaxial growths.

### Relationship of Concentrations in SJ Region

In the multi-epitaxial method, the relationship of impurity concentrations between the SJ region 100 and the silicon carbide semiconductor substrate 10 and the drift layer 20 is as follows. First, regarding the n-type region, the silicon carbide semiconductor substrate 10 has the highest concentration. The drift layer 20 is designed to have concentration the same as or lower than that of the pillar region 21. Next, regarding the p-type region, although the relationship of high and low concentrations is different depending on a design of the charge balance in the SJ region 100, basically, if there is a balanced state within a range that a total amount of donors/a total amount of acceptors is 0.5 to 2, that is, with a relationship in which one is twice or half as much as the other, within a certain plane in the SJ region 100 in the depth direction, it can be considered that there substantially is a charge balance. Note that this applies only to the active region.

### Concentration Distribution in SJ Region in Depth Direction

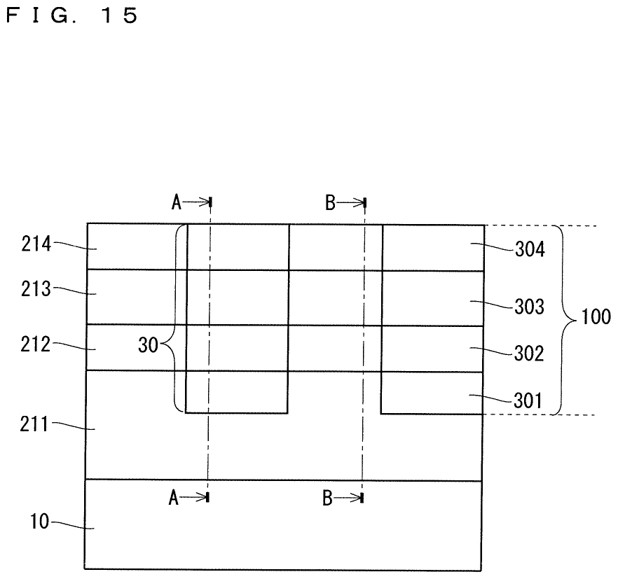

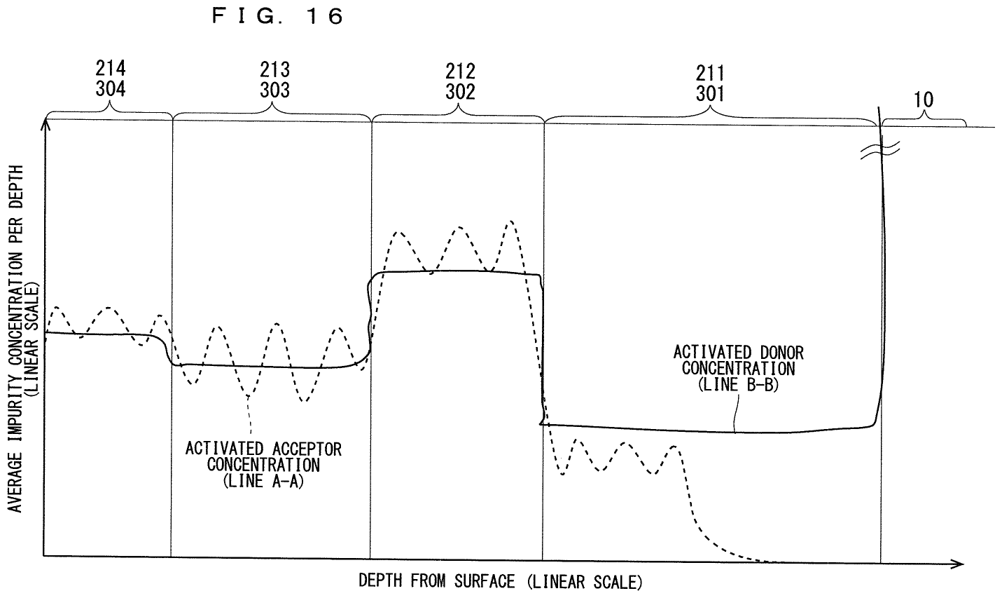

A cross-sectional configuration of the SJ region 100 when the multi-epitaxial method is repeated four times is illustrated in FIG. 15 as a specific example of the first embodiment, and a profile of average impurity concentration of acceptor ions and donor ions in the SJ region 100 in the depth direction is shown in FIG. 16. Note that the first embodiment presupposes that acceptor impurities in ion implantation are activated in an activation annealing process to be described later, and also the profile of FIG. 16 shows only the profile of activated donors and acceptors. Further, in this specification, basically, quantitative discussions regarding impurity concentrations in a case of discussing the charge balance are all held only regarding activated impurities.

As illustrated in FIG. 15, in the cross-sectional configuration of the SJ region 100 when the multi-epitaxial method is repeated four times, an n-type pillar region 211 at the first level, an n-type pillar region 212 at the second level, an n-type pillar region 213 at the third level, and an n-type pillar region 214 at the fourth level, and a p-type pillar region 301 at the first level, a p-type pillar region 302 at the second level, a p-type pillar region 303 at the third level, and a p-type pillar region 304 at the fourth level are formed.

In FIG. 16, the horizontal axis indicates the depth from the surface of the SJ region 100 on a linear scale, and the vertical axis indicates the average impurity concentration in the depth direction on a linear scale, and indicates a profile of the impurity concentration of acceptor ions taken along the line A-A in FIG. 15 with a broken line, and indicates a profile of the impurity concentration of donor ions taken along the line B-B in FIG. 15 with a solid line.

As illustrated in FIG. 16, for example, when donor concentration of the epitaxial layer is increased as in the n-type pillar region 212 at the second level, the ion implantation amount is increased to increase acceptor concentration as in the p-type pillar region 302 at the second level, such that the charge balance in a certain depth direction is maintained.

Further, when the epitaxial film thickness is increased as illustrated by the n-type pillar region 213 at the third level, the implantation amount energy and the dosage are adjusted according to the increase of the epitaxial film thickness to distribute an implantation peak as in the p-type pillar region 303 at the third level, such that the charge imbalance to be generated is minimized as a result.

### Method of Forming MOSFET Region

Next, a method of forming the MOSFET region 200 will be described with reference to FIG. 2. First, in order to form the MOSFET region 200, an n-type epitaxial layer is formed on the SJ region 100. In this case, by controlling an epitaxial condition such that the impurity concentration is equal to that of the JFET region 22, the number of processes can be reduced.

Further, after the epitaxial layer is formed with low impurity concentration of the n type, for example, 1×10¹⁴ cm⁻³, the concentration may be increased up to concentration equal to that of the JFET region 22 through ion implantation. In this case, unevenness of the impurity concentration can be reduced than that in a case in which the n-type epitaxial layer is formed with epitaxial growth, and accordingly unevenness of products can be reduced and a yield can be increased.

The impurity concentration of the JFET region 22 may be formed with impurity concentration higher than the impurity concentration of the drift layer 20 and that of the pillar region 21, or may be formed with impurity concentration the same as those. When the impurity concentration of the JFET region 22 is higher than those of the drift layer 20 and the like, the JFET resistance can be made to be low resistance, and when the impurity concentration of the JFET region 22 is the same as those of the drift layer 20 and the like, the implantation process can be omitted to reduce costs. The impurity concentration of the JFET region 22 may be, for example, 5×10¹⁶ to 1×10¹⁸ cm⁻³. Further, as long as the impurity concentrations of the drift layer 20 and the pillar region 21 are within a range of 1×10¹⁵ to 1×10¹⁷ cm⁻³, operation as a MOSFET is fulfilled. Note that, although the drift layer 20 and the pillar region 21 have impurity concentration lower than that of the JFET region 22 in general, finer pillar pitches in the SJ-SiC-MOSFET allow for higher concentration thereof. In that case, the concentration may be increased up to concentration equal to that of the JFET region 22. Note that the thickness of the n-type epitaxial layer formed on the SJ region 100 is approximately 1 to 4 μm.

Next, acceptor ions of Al or the like are implanted into the n-type epitaxial layer through ion implantation, so as to form the n-type body region 32. The impurity concentration of the body region 32 may be, for example, 5×10¹⁷ to 1×10¹⁹ cm⁻³. The impurity concentration of the body region 32 is set higher than that of the JFET region 22. The depth of the body region 32 may be approximately 0.5 to 1.5 μm. When the body region 32 is deep, a channel length can be increased, and short circuit capacity can be increased. Further, the body region 32 can be formed by providing a p-type epitaxial layer.

Next, the source region 23 and the body contact region 33 are formed through ion implantation and photolithography. The n-type source region is formed through implantation of impurities such as nitrogen (N) or phosphorus (P), and the impurity concentration thereof is within a range of 1×10¹⁸ to 1×10²¹ cm⁻³, and is a value exceeding the p-type impurity concentration of the body region 32. The body contact region 33 is obtained by forming p-type impurities such as Al and B with impurity concentration of 5×10¹⁸ to 1×10²² cm⁻³, which exceeds that of the body region 32. Note that the depths of the source region 23 and the body contact region 33 are approximately 200 nm to 1.0 μm.

Next, an SiO₂ film is formed on a substrate after the source region 23 and the body contact region 33 are formed, a resist material is applied onto the substrate, the resist material is patterned with photolithography to form a resist mask, the SiO₂ film is patterned with dry etching using the resist mask, and a mask for trench etching is thereby prepared. Subsequently, with reactive ion etching (RIE) or the like, a trench penetrating the body region 32 from the substrate surface to reach the JFET region 22 is formed. The depth of the trench is approximately 0.8 to 3.0 μm, p-type impurities are further introduced below the trench through ion implantation, and the electric field protection region 31 is thereby formed. The electric field protection region 31 may have impurity concentration of, for example, 1×10¹⁷ to 5×10¹⁸ cm⁻³, and have depth of approximately 0.2 to 1.0 μm. In this case, if the implantation mask for forming the electric field protection region 31 is also used as the mask for trench etching, the number of processes can be reduced.

Next, using a thermal treatment device, annealing is performed in an inert gas atmosphere of an argon (Ar) gas or the like at the temperature of 1300 to 1900° C. for 30 seconds to 1 hour. Through the annealing, implanted N and Al ions are electrically activated.

Next, the surface of the silicon carbide layer is thermally oxidized to form a silicon oxide film of a desired thickness, and the gate insulation film 50 is thereby formed. The gate insulation film 50 covers the inner surface of the trench, and also covers the surfaces of the source region 23 and the body contact region 33.

Next, a polycrystalline silicon film having conductivity is formed on the gate insulation film 50 with the low pressure CVD method, the polycrystalline silicon film is patterned, and the gate electrode 60 is thereby formed. The polycrystalline silicon film fills the trench surrounded by the gate insulation film 50 and also covers the top of the source region 23 and the body contact region 33, while the polycrystalline silicon film out of the trench is removed by being patterned with etching.

Next, a silicon oxide film is formed with the low pressure CVD method to form the interlayer insulation film 51. In this case, the gate insulation film 50 remaining on the substrate is integrated with the interlayer insulation film 51.

Next, an opening penetrating the interlayer insulation film 51 and the gate insulation film 50 to reach the body contact region 33 and the source region 23 in the active region is formed.

Next, a metal film containing, for example, nickel (Ni) as a main component is formed with the sputtering method or the like, then thermal treatment is performed at the temperature of 600 to 1100° C. to cause the metal film containing Ni as a main component and the silicon carbide layer in the opening to react with each other, and metal silicide is thereby formed between the silicon carbide layer and the metal film. Next, the metal film other than the metal silicide formed through the reaction is removed with wet etching. With this, the remaining metal silicide forms the ohmic electrode 70.

Next, a metal film containing Ni as a main component is formed on the back surface being a second main surface of the silicon carbide semiconductor substrate 10, and thermal treatment is performed at the temperature of 600 to 1100° C., and an ohmic electrode (not illustrated) is thereby formed.

Next, a wire metal made of Al or the like is formed on the front surface side of the silicon carbide semiconductor substrate 10 with the sputtering method or the vapor deposition method, and by working the wire metal into a predetermined shape with the photolithography technology, the source electrode 80, the gate pad 81, and the gate wiring 82 are formed as illustrated in FIG. 1. The source electrode 80 comes in contact with the ohmic electrode 70, and the gate pad 81 comes in contact with the gate electrode 60.

Finally, a drain electrode 83 being a metal film is formed on the surface of the ohmic electrode (not illustrated) formed on the back surface of the silicon carbide semiconductor substrate 10, and the SJ-SiC-MOSFET illustrated in FIG. 1 to FIG. 5 is thereby completed.

### Operations

Next, operations of the SJ-SiC-MOSFET 1000 will be described. In the following, description will be given by taking an example of an SJ-SiC-MOSFET whose semiconductor material is 4H-silicon carbide. A power device performs various operations in a power conversion device such as an inverter. As operations and states in which the present disclosure exerts its effects, an OFF state and an ON state will be described. Description for other operation modes will be omitted.

### OFF State

### Full Depletion

First, a general OFF state common to the n-channel SJ-SiC-MOSFET 1000 will be described. In the OFF state, a gate voltage is equal to or lower than a threshold and is, in general, 0 V or minus several volts, and corresponds to a high resistance state, with the n channel not being formed. In an inverter, in the OFF state, a high voltage is applied to a drain of an element. In a case of the SJ-SiC-MOSFET, first, when a positive voltage starts to be applied to the drain, a reverse bias is applied to the pn junction between the pillars in the SJ region 100. Thus, the depletion layer extends toward the horizontal direction of the SJ region 100. When the voltage exceeds a certain voltage, the n-type pillar region 21 and the p-type pillar region 30 are fully depleted. With this, resistance between the drain and the source is significantly increased, and thus the OFF state can be maintained. In this case, without a full charge balance, even when one is fully depleted, the other is not fully depleted, and thus an unnecessary electric field is generated.

### Avalanche

In the OFF state, when a drain voltage is further increased, an electric field in the vertical direction is increased in turn. Depending on a design, as a portion to have a maximum electric field, a maximum electric field is mainly applied to the pn junction of the body region 32 and the JFET region 22 in a lowermost part or an uppermost part of the SJ region 100. When the maximum electric field in this case exceeds a breakdown electric field (approximately 3 MV/cm) of SiC, an electrical breakdown occurs due to the avalanche current.

### Optimal Design

As described above, in the design of the SJ-SiC-MOSFET, it can be understood that adjustment of the charge balance of the pillars is significantly important. As a method for optimization of the design of the pillars, for example, the Fujihira's theory (T. Fujihira “Theory of semiconductor superjunction devices” (Jpn. J. Appl. Phys., Vol. 36 (1997), pp. 6254 to 6262) is famous. The present disclosure also presupposes implementation of the SJ region optimized based on the Fujihira's theory.

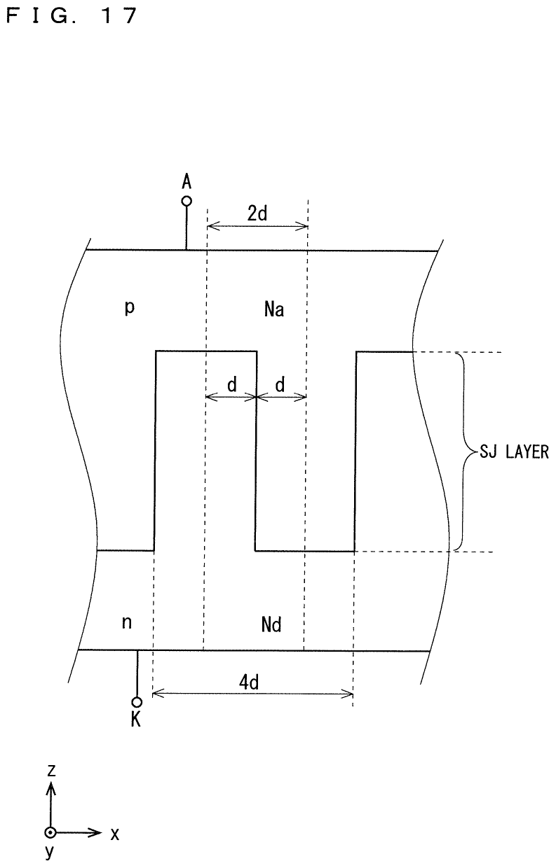

As an example, results of the optimal design of the SJ region 100 will be described. Here, for the sake of simplification, a case employing a simple pn diode structure as illustrated in FIG. 17 with a p-type pillar and an n-type pillar having the same widths will be described.

In FIG. 17, an anode A containing p-type impurities with concentration Na and a cathode K containing n-type impurities with concentration Nd are provided such that their pillar layers are alternated with each other, and a half of the width of each pillar layer is represented by d. Note that a part in which the p-type pillar and the n-type pillar are formed is referred to as an SJ layer.

When the optimal design based on the Fujihira's theory is carried out, characteristic on-resistance of the SJ layer and the breakdown voltage of the semiconductor device is determined by the following expression (1).

$${R}_{on . sp} . = \frac{4 d {V}_{B}}{μ {ε}_{S} {E}_{C}^{2}} \qquad ( 1 )$$

In the above expression (1), R_{on.sp.} represents the characteristic on-resistance, d represents the half of the pillar width, V_{B} represents the breakdown voltage, μ represents mobility, εₛ represents permittivity of the semiconductor, and E_{c} represents the breakdown electric field.

Under a condition of the optimal design in which expression (1) is satisfied, the maximum electric field when the breakdown voltage V_{B} is applied to the cathode K is exactly equal to the breakdown electric field E_{c}, details of which are shown in the following expressions (2) and (3).

E_{c}=Ezmax+Exmax (2)

Ezmax=Exmax (3)

In the above expressions (2) and (3), E_{zmax} represents the maximum electric field at the center portion of the SJ layer in the vertical direction, and Eₓₘₐₓ represents, similarly, the maximum electric field at the center portion of the SJ layer in the horizontal direction.

In a case of the pn diode structure illustrated in FIG. 17, the p-type pillar and the n-type pillar have the same widths and impurity concentrations. When a cathode voltage is increased to a certain voltage, the depletion layer spreads into the p-type pillar and the n-type pillar from the pn junction surface by the width d. In this case, the n-type pillar and the p-type pillar are fully depleted, and the maximum electric field Eₓₘₐₓ is applied in the horizontal direction at the center portion of the SJ layer and in the vertical direction at upper and lower end portions of the pillar center portion of the SJ layer. At the time of an electrical breakdown, the maximum electric field E_{zmax} is applied to the center portion of the SJ layer in the vertical direction, and the electric field of Eₓₘₐₓ+E_{zmax} is applied to the upper and lower end portions of the pillar center portion of the SJ layer in the vertical direction, and when the value reaches the breakdown electric field, an electrical breakdown occurs. In a case of the structure, as shown in expression (3), by designing the maximum electric fields in the vertical direction and the horizontal direction to be equal to each other, the breakdown voltage and the on-resistance can be maximized.

The impurity concentration N of the n-type pillar and the p-type pillar in the optimal design can be calculated according to the following expression (4), using expression (2), expression (3), and Gauss's law.

$${Q}_{x} = {ϵ}_{S} {E}_{xm ax} = \frac{{ε}_{S} {E}_{C}}{2} = qNd \qquad ( 4 )$$

$$N = \frac{{ϵ}_{S} {E}_{C}}{2 d q}$$

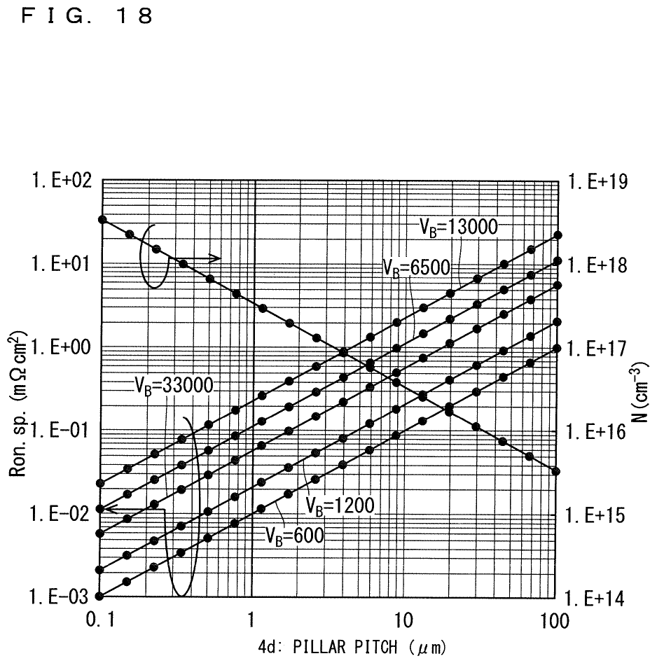

Based on the above expressions (4) and expression (1), results of calculation of a relationship between the pillar repetition period (pillar pitch), the on-resistance, and the impurity concentration N are shown in FIG. 18. In FIG. 18, the horizontal axis indicates 4d (μm) being the pillar pitch, the left vertical axis indicates the characteristic on-resistance R_{on.sp.} (mΩ cm²), and the right vertical axis indicates the impurity concentration N (cm⁻³).

In FIG. 18, characteristics between the pillar pitch and on-resistance are plotted when the breakdown voltage V_{B} is 600 V, 1200 V, 3300 V, 6500 V, and 13000 V.

With reference to FIG. 18, it can be understood that there is a tendency that the on-resistance is reduced as the pillar pitch (4d) is reduced. It can also be understood that the impurity concentration is increased as the pillar pitch (4d) is reduced. Thus, by reducing the pillar pitch and reducing the on-resistance, it can be said that there is a tendency that a total amount of charges necessary for discharge and charge of the pillars is simultaneously increased.

### At Time of Holding Breakdown Voltage

Next, characteristics of the silicon carbide semiconductor device manufactured with the manufacturing method of the present disclosure exerted at the time of holding the breakdown voltage, that is, at the time of the OFF state, will be described. At the time of holding the breakdown voltage, the charge balance state of the SJ region 100 is a significantly important parameter, and effects of the manufacturing method of the present disclosure are most notably exhibited. First, electric field distribution at the time of holding the breakdown voltage with an ideal charge balance will be described, and subsequently behaviors when the charge balance is disturbed will be described, and then a specific control method and effects of feedforward implantation of the present disclosure will be described.

### Ideal Case

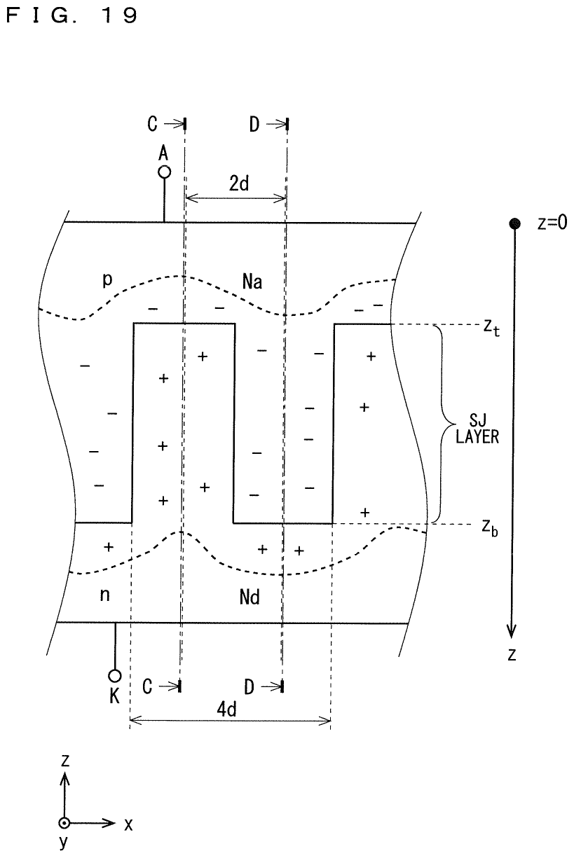

In a case of the pn diode structure illustrated in FIG. 17, the acceptor concentration and the donor concentration are optimally designed, and a state at the time of holding the breakdown voltage when the charge balance is established, that is, at the time of voltage application immediately before an electrical breakdown, is schematically illustrated in FIG. 19.

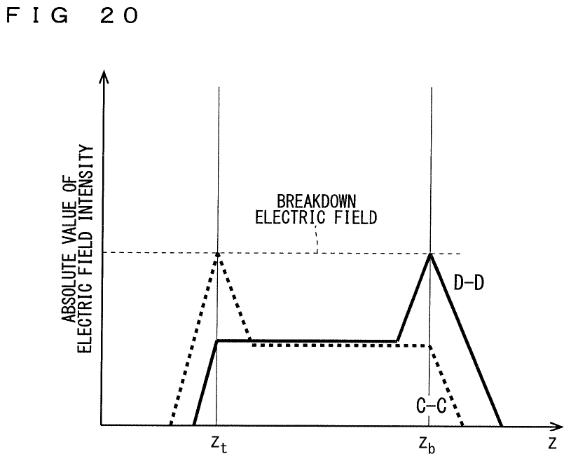

In FIG. 19, the p-type pillar and the n-type pillar are fully depleted, and electric field distribution in which the absolute value of electric field intensity along the line C-C and the line D-D of the n-type pillar and the p-type pillar in this case is plotted with respect to the depth direction (z-axis) is shown in FIG. 20. Note that, in FIG. 19, the surface of the anode A is represented by z=0, a tip of the n-type pillar is represented by zₜ, and a base of the n-type pillar is represented by z_{b}.

In FIG. 20, the horizontal axis indicates a position in the depth direction, and the vertical axis indicates the absolute value of the electric field intensity. In an ideal state, the SJ layer has a full charge balance, and thus the electric field distribution in the SJ layer is uniform, and the electric field distribution along the line C-C and the electric field distribution along the line D-D are distributions in line symmetry. In a macroscopic view, this means that it appears that there is no space charge in the drift layer, that is, it appears to be an insulator, and the SJ layer in this case has the maximum breakdown voltage.

### Case in which Only Epitaxial Concentration Varies

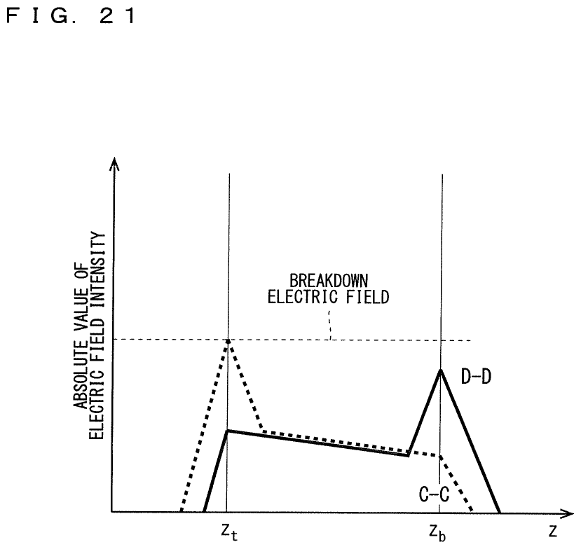

Next, a case in which the impurity concentration of only the p-type region varies in the pn diode structure illustrated in FIG. 17 is considered. First, when the concentration of the p-type region is increased, as illustrated in FIG. 21, the electric field distribution along line the C-C and the electric field distribution along the line D-D become asymmetrical electric field distributions. As a mechanism therefor, first, the p-type pillar is fully depleted due to increase of the voltage and extension of the depletion layer. Subsequently, to deplete the remaining n-type pillar, the p-type region on the upper portion of the p-type pillar needs to be depleted. Thus, the line of electric force from donor ions in the newly depleted n-type pillar is terminated by acceptor ions in the p-type region. Accordingly, the electric field of the SJ layer is increased in a region with low z, that is, a region closer to the p-type region. In a macroscopic view, it can be considered that the SJ layer is an n-type region being thin for the charge imbalance. An application voltage has a value obtained by integrating the electric field intensity with a path from the anode A to the cathode K, and thus the breakdown voltage is reduced in proportion to reduction of the area of the graph of the electric field distribution of FIG. 21 due to the charge imbalance.

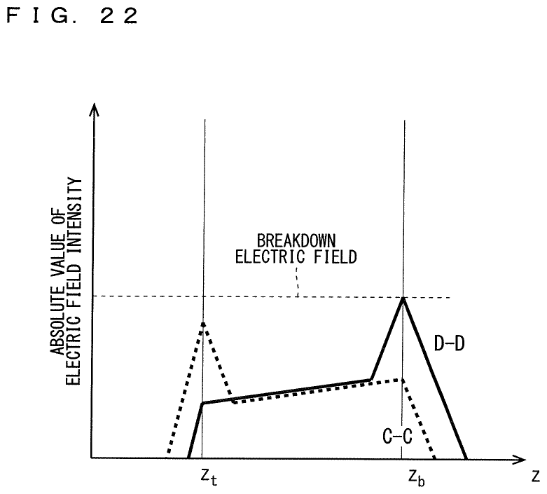

In contrast, when the impurity concentration of the n-type pillar is low, as illustrated in FIG. 22, in contrast to FIG. 21, there are characteristics with the electric field distribution along the line C-C and the electric field distribution along the line D-D being opposite to each other. In other words, in a macroscopic view, it can be considered that the SJ layer is a p-type region thin for the charge imbalance. The breakdown voltage is reduced in proportion to reduction of the area of the graph of the electric field distribution of FIG. 22 due to the charge imbalance.

### Case in which Only Concentration is Fed Forward

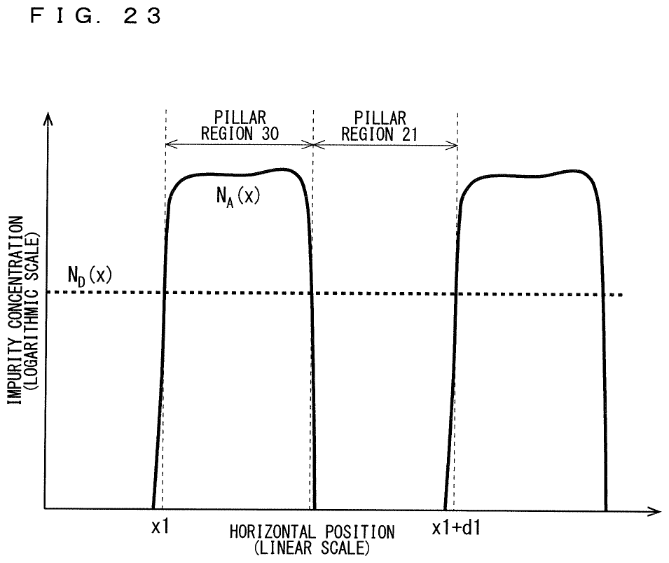

Next, a specific method of feeding the carrier concentration of the drift layer 20 forward to the ion implantation process and effects thereof will be described. FIG. 23 is a graph showing a profile of the impurity concentration at a certain depth of the SJ region 100 in cross-section of FIG. 2. First, as a premise, an amount indicating a degree of charge balance, that is, a charge balance amount, is defined, and then a method of maintaining the charge balance amount at a fixed value will be presented.

In FIG. 23, the horizontal axis corresponds to the x-axis of FIG. 2, and the vertical axis indicates the impurity concentration on a logarithmic scale. In FIG. 23, acceptor ion concentration N_{A}(x) is distributed with a period of a pillar pitch d1 in the x-axis direction corresponding to the pillar region 30. Note that, regarding distribution N_{D}(x) of donor concentration N_{D}, on the assumption that the epitaxial concentration is uniform, it can be considered that N_{D}(x)=N_{D}=fixed value. Here, average donor concentration N_{Dave} per pillar pitch d1 in the SJ region 100 is shown by N_{Dave}=N_{D}·d1/d1=N_{D}. Further, the average number N_{Aave} of acceptors per pillar pitch d1 is shown by the following expression (5).

$${N}_{A a v e} = \frac{1}{d 1} {\int }_{x 1}^{x 1 + d 1} {N}_{A} ( x ) d x \qquad ( 5 )$$

Using the above values, a charge balance amount α is defined according to the following expression (6).

$$α = \frac{{N}_{D a ν e} - {N}_{A a v e}}{{N}_{D a v e}} \qquad ( 6 )$$

The charge balance amount α represents the amount of deficiency and excess of average concentrations of donors and acceptors when the donors are positive and the acceptors are negative per pillar pitch d1.

When α=0, N_{Dave}=N_{Aave} is satisfied, and this is a state of the full charge balance. When a has a positive value, the donors are excessive, whereas when a has a negative value, the acceptors are excessive. Note that, as described above, concentrations of only the activated acceptors and donors are employed.

For example, at the time of center design, when the design is employed such that α=0, that is, N_{Dave}=N_{Aave}=N_{mid}, and the concentration of N_{Dave} is increased higher than the design center value N_{mid} by 10%, a total amount N_{Dtot} of donors is represented by N_{Dtot}=1.1·N_{mid} and a total amount N_{Atot} of acceptors is represented by N_{Atot}=N_{mid}. When this is substituted in expression (6), α=(1.1−1)/1.1˜0.091 is obtained.

This means that the net depletion layer impurity concentration in the SJ region 100 at a certain depth at the time of full depletion is +N_{mid}·0.091. In general, as α is closer to 0, there are greater effects of increase of the breakdown voltage due to the SJ structure. In a structure not employing the SJ structure, that is, in a case where N_{Atot}=0, α=1, and thus employing a design such that the absolute value of α is smaller than this, that is, |α|<1, can bring effects of flat electric field distribution in the depth direction due to the SJ structure, that is, increase of the breakdown voltage due to neutralization of the drift layer in a macroscopic view.

In the present disclosure, an evaluation process such as CV measurement is carried out, such that the average concentration of the drift layer 20 within the wafer surface is set to known concentration. Thus, the average donor concentration N_{Dave} within the wafer surface in expression (6) is known.

First, unevenness of the average donor concentration N_{Dave} within the wafer surface is ignored for the sake of simplification. In this case, a resultant opening width of the implantation mask for implantation of the acceptor ions is represented by Lp, and the pillar region 30 having the same width as the resultant opening width Lp of the implantation mask is formed. In this case, when the average donor concentration within the wafer surface varies by ±β%, the average donor concentration N_{Dave} shifts from the design center value by ±β%. Here, β is a positive real number of 50 or less. Thus, by changing the change amount of the total amount N_{Dtot} of donors by ±β% with feedforward of acceptor dosage Dₐ, the SJ region 100 can be completed without changing the charge balance amount α, and the effects according to the present disclosure can be fully achieved.

When the effects according to the present disclosure are to be achieved with a simpler method, for a condition of the dosage implemented in feedforward, a predetermined value prepared in advance can be selected according to the impurity concentration of the drift layer 20. For example, a process in which the donor concentration varies by ±β% is assumed for the donor concentration N_{D} as the design center. Here, β% is, for example, 30. The acceptor dosage Dₐ is classified into cases in which the donor concentration N_{D} is larger and smaller than the design center, and a determination can be made such that (+β/2)% is employed when the donor concentration N_{D} is larger and (−β/2)% is employed when the donor concentration N_{D} is smaller. In this case, as compared to a case in which feedforward implantation is not carried out, the unevenness of the charge balance amount can be reduced by half. Similarly, the acceptor dosage is classified into cases of n regions with the value of the donor concentration N_{D} being within a range of ±β% with respect to the design center, and a representative value may be prepared for each region. In this case, the unevenness of the charge balance amount can be reduced to 1/n.

### Case in which Opening Width is also Fed Forward

Next, a case in which the opening width Lp of the resist for forming the implantation mask for implantation of the acceptor ions is also fed forward will be considered. It is assumed that the donor concentration N_{D} shifts from the design center by ±β%, and the opening width Lp of the resist shifts from the design center by ±γ%. Here, γ is a positive real number of 30 or less. For the sake of simplification, ±β is represented by β1 and ±γ is represented by γ1. Note that β and γ are each a real number whose absolute value is 30 or less. When feedforward is not carried out, the total amount N_{Atot} of acceptors is shown by the following expression (7), where N_{Atot0} represents the design center.

$${N}_{Atot} = {N}_{Atot 0} \cdot ( 1 + \frac{{γ}_{1}}{100} ) \qquad ( 7 )$$

Here, a charge balance amount α₀ of the design center is shown by the following expression (8), where N_{Dtot0} represents the design center of the total amount N_{Dtot} of donors.

$${α}_{0} = \frac{{N}_{Dtot 0} - {N}_{Atot 0}}{{N}_{Dtot 0}} \qquad ( 8 )$$

Here, when the opening width Lp of the resist and the unevenness of the donor concentration N_{D} are fed forward, the acceptor dosage Dₐ is set to a value changed with respect to a design center Dₐ₀ as shown in the following expression (9).

$${D}_{a} = {D}_{a 0} \cdot \frac{1 + \frac{{β}_{1}}{100}}{1 + \frac{{γ}_{1}}{100}} \qquad ( 9 )$$

In this case, a total amount N_{Atot1} of acceptors per pillar pitch is multiplied by a coefficient of expression (9) representing the total amount N_{Atot} of acceptors when feedforward is not implemented, and is thus shown by the following expression (10).

$${N}_{Atot 1} = {N}_{Atot} \cdot \frac{1 + \frac{{β}_{1}}{100}}{1 + \frac{{γ}_{1}}{100}} \qquad ( 10 )$$

Accordingly, the charge balance amount α with feedforward implantation of expression (10) is shown by the following expression (11).

$$α = \frac{{N}_{D t o t 0} \cdot ( 1 + \frac{{β}_{1}}{100} ) - {N}_{Atot} \cdot \frac{1 + \frac{{β}_{1}}{100}}{1 + \frac{{γ}_{1}}{100}}}{{N}_{Dtot 0} \cdot ( 1 + \frac{{β}_{1}}{100} )} \qquad ( 11 )$$

$$= \frac{{N}_{Dtot 0} - {N}_{Atot} \cdot \frac{1}{1 + \frac{{γ}_{1}}{100}}}{{N}_{Dtot 0}} = \frac{{N}_{D t o t 0} - {N}_{Atot 0}}{{N}_{Dtot 0}} = {α}_{0}$$

According to above expression (11), by performing feedforward implantation shown in expression (9), a coefficient due to the unevenness of the drift layer 20 and a coefficient due to the unevenness of the opening width of the resist can be canceled out, and thus the charge balance amount α₀ at the design center can be maintained, and the effects according to the present disclosure can be fully achieved.

As described above, when feedforward implantation is executed with the opening width of the resist being included as well, similarly to a case in which only the carrier concentration is fed forward, the process can be simplified by making a selection among a set of predetermined conditions prepared in advance. In this case, a certain management width can be provided for the unevenness ±β% of the epitaxial concentration and the unevenness ±γ% of the resist opening width, a matrix can be formed with each of β and γ being divided into a limited number of sections within the management width, and table data of the implantation amount for the matrix can be thereby formed.

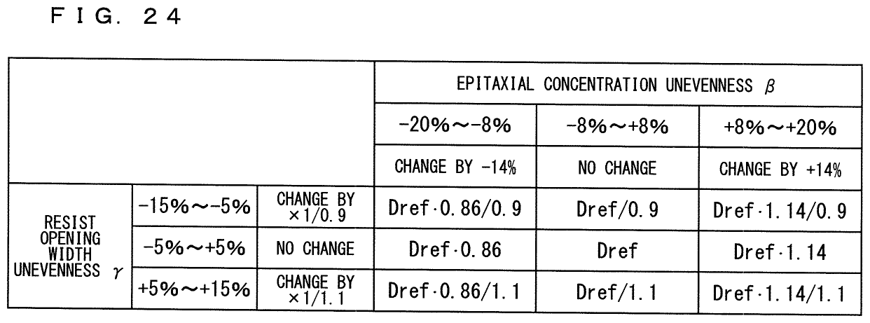

An example of the table data is shown in FIG. 24. FIG. 24 shows an example in which the unevenness γ of the resist opening width is divided into ranges of −15% to −5%, −5% to +5%, and +5% to +15%, and the unevenness β of the epitaxial concentration is divided into ranges of −20% to −8%, −8% to +8%, and +8% to +20%. Further, predetermined values prepared in advance are set for each of the unevenness ranges of the resist opening width and each of the unevenness ranges of the epitaxial concentration, with the resist opening width of the design center being represented by x1 and the dosage of the design center being represented by Dref.

For example, when only the epitaxial concentration varies within a range of −20% to −8%, the dosage is set to −14%, whereas when the epitaxial concentration varies in a range of +8% to +20% and the resist opening width varies in a range of +5% to +15%, the dosage is set to Dref·1.14/1.1.

As shown in expression (9), the dosage for feedforward implantation can be set to have a positive correlation for the unevenness of the epitaxial concentration and a negative correlation for the unevenness of the resist opening width.

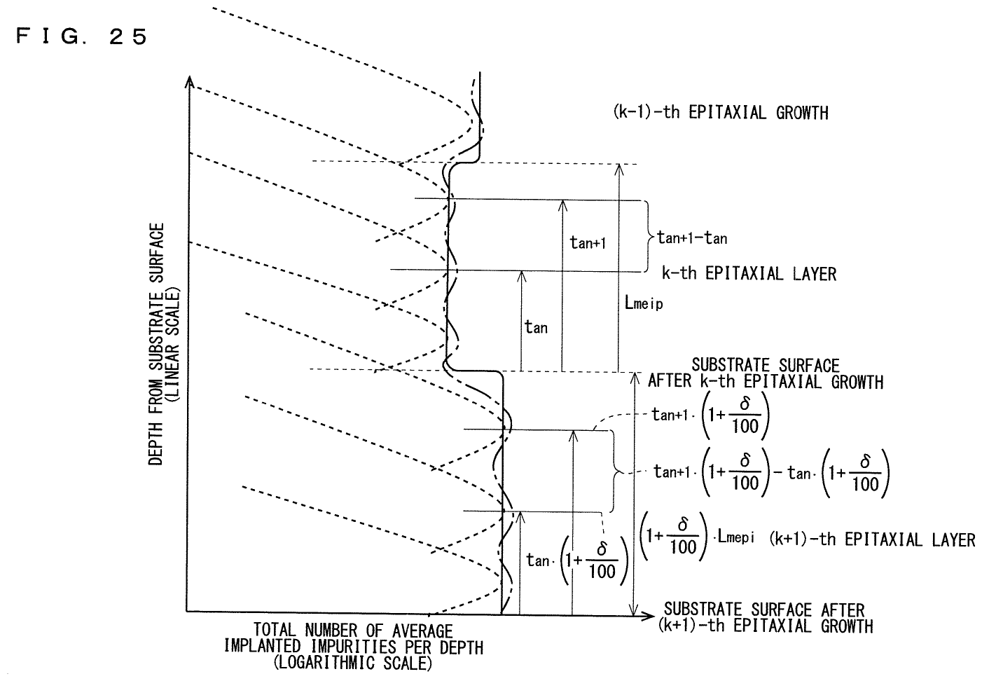

Finally, a method of feeding the film thickness of the drift layer 20 forward to the acceptor implantation amount and the implantation energy will be described. As a basic idea, intervals of peaks of the implantation energy are increased and decreased according to increase and decrease of the film thickness, with the number of times of implantation being fixed. The outline thereof is shown in FIG. 25.

FIG. 25 is an implantation profile in which the horizontal axis indicates implanted impurity concentration per depth on a logarithmic scale, and the vertical axis indicates the depth form the substrate surface on a linear scale. First, an example in which the unevenness of the average film thickness within the wafer surface generated when the second and subsequent epitaxial growths are performed is fed forward to the implantation energy in a multi-epitaxial structure will be described.

Specifically, when the average film thickness varies by ±δ%, for example, the implantation energy in each stage of the multi-stage implantation is changed by ±δ%, primarily in the n-th stage. In this case, the implantation depth of the peak concentration in the n-th stage implantation at the design center from the epitaxial layer surface is represented by tₐₙ, and the film thickness of each epitaxial layer at the design center is represented by Lₘₑₚᵢ. FIG. 25 shows a case in which the epitaxial layer formed in the k-th epitaxial growth completes at the design center, and also shows a case in which the average film thickness of the epitaxial layer formed in the (k+1)-th epitaxial growth completes with +δ%.

By carrying out such feedforward, the implantation energy is in proportion to the implantation depth, and thus as shown in FIG. 25, distribution of the peak positions in multi-stage implantation of the acceptors can be equally increased and reduced, and accordingly the unevenness of the charge imbalance in the depth direction can be reduced.

Specifically, by changing the intervals of implantation peaks, that is, a difference tₐₙ₊₁−tₐₙ between the implantation depths in the n-th stage and the (n+1)-th stage, by ±δ% in proportion to the unevenness of the film thickness, the implantation depth in each stage can be uniformly increased and decreased. Note that, in this specification, for the sake of simplification, the implantation depth tₐₙ and the implantation energy Eₐₙ are in proportion to each other. However, for example, when a method of performing implantation via a through film made of SiO₂ or the like for the purpose of increase of the concentration of the epitaxial layer surface and the like is used, the implantation energy Eₐₙ is represented by energy E₀ necessary for passing through the through film, and the energy E₀ is controlled to change by ±δ% with respect to net energy Eₐₙ′ implanted into SiC, which is subtracted from the implantation energy Eₐₙ.

As described above, when the film thickness of the drift layer 20 is fed forward to determination of the implantation energy in the multi-stage implantation process for forming the pillar region 30, and the implantation dosage is not to be changed, the concentration at the peak of distribution formed through implantation of acceptor ions with respect to the film thickness is increased and decreased in inverse proportion to the unevenness of the film thickness by δ%. In other words, for example, when the film thickness is increased by δ%, the energy interval of the multi-stage implantation needs to be increased, and the average acceptor concentration of the pillar region 30 is thereby reduced by δ%. Thus, when feedforward to the implantation energy is implemented based on the film thickness, it is desirable to perform feedforward of the dosage corresponding to sparsity and density of the multi-stage implantation profile, in addition to the feedforward to the epitaxial concentration.

Specifically, when the film thickness is increased and decreased by δ%, by changing the implantation dosage Dₐ by Dₐ₀/(1±δ/100) with respect to the design center Dₐ₀ after setting the implantation energy with the method described above, desired acceptor concentration can be implemented, and the charge balance amount can be optimally maintained.

Although the film thickness feedforward method of the first embodiment described above describes the second and subsequent epitaxial growths, the present disclosure can be applied to the first epitaxial growth as well. In a case of the first epitaxial growth, since there is no pillar region 30 formed in a previous epitaxial growth, the effects as described above may not be achieved. However, change of a distance between the lower end of the pillar region 30 and the silicon carbide semiconductor substrate 10 due to the film thickness can be reduced, and thus electric field distribution can be reduced and certain effects can be achieved regarding increase of the breakdown voltage.

### ON State

The ON state of the SJ-SiC-MOSFET 1000 will be described with reference to FIG. 2. When a positive voltage of a threshold or higher, for example, a voltage of approximately 15 V, is applied as a gate voltage, an n-type inversion layer channel is induced in a channel region immediately below the gate insulation film 50, that is, an interface between the body region 32 and the gate insulation film 50 interposed between the n-type pillar region 21 and the source region 23. With this, the source region 23 and the JFET region 22 are connected with low resistance, and as a result, the ON state in which the drain electrode 83 and the source electrode 80 are connected with low resistance is achieved.

The on-resistance of the SJ-SiC-MOSFET 1000 is shown by the following expression (12).

Ron.sp.=R_{sub}R_{driftSJ}+Rch+R_{JFET} (12)

In the above expression (12), when the on-resistance is represented by R_{on.sp.}, the on-resistance R_{on.sp.} is determined by the sum of substrate resistance R_{SUB}, resistance R_{driftSJ} of the drift layer 20 and the pillar region 21, resistance R_{JFET} of the JFET region 22, and channel resistance R_{ch}. Among the above, a component with which the effects according to the present disclosure can be achieved the most is the resistance R_{driftSJ}.

### Comparison to SJMOSFET of Related Art

A comparison to an SJ-SiC-MOSFET of related art is considered. In a case of an SJ-SiC-MOSFET of a multi-epitaxial method of related art, even when the epitaxial concentration varies, the impurity concentration of the pillar region 21 remains as it is, and the charge imbalance is generated according to the unevenness of the epitaxial concentration, and the breakdown voltage is thus reduced. Thus, in view of reduction of the breakdown voltage, the film thickness of the drift layer needs to be increased to secure the breakdown voltage. As a result, the drift layer resistance is increased in inverse proportion to the increase of the film thickness. When the epitaxial concentration varies to be low in particular, in addition to this, the drift layer resistance is increased in inverse proportion to the reduction of the carrier concentration, and conduction loss in the ON state is notably increased.

In contrast, in the SJ-SiC-MOSFET 1000, acceptor ion implantation can be performed on the condition with feedforward of the film thickness and the epitaxial concentration of the drift layer 20 and the implantation resist opening width, and thus the charge imbalance caused due to the unevenness of the epitaxial concentration, the implantation resist opening width, and the film thickness can be significantly reduced, and the unevenness of the breakdown voltage can be remarkably reduced. Thus, as compared to the SJ-SiC-MOSFET of related art, even when the film thickness of the drift layer is reduced, the breakdown voltage can be maintained, and the on-resistance can be reduced in proportion to the reduction of the film thickness of the drift layer. Thus, the effects allowing for increase of the breakdown voltage can be achieved, without increasing the on-resistance.

The first embodiment described above mainly focuses on measuring the unevenness of the impurity concentration of the drift layer 20 and performing feedforward to the dosage of the ion implantation process with small unevenness in principle, and further the amount of ions implanted into the drift layer 20 effectively through measurement of the implantation resist opening width is fed forward as well. Further, by measuring the unevenness of the film thickness of the epitaxial layer and feeding this forward to the ion implantation energy and the dosage, the effects according to the present disclosure can further be enhanced. In contrast, the above feedforward to the ion implantation energy and the dosage need not necessarily be simultaneously applied to all of the parameters, and only the feedforward to the epitaxial concentration may be performed, only the feedforward to the resist opening width may be performed, only the feedforward to the film thickness may be performed, or some of these may be combined. In that case, the effects according to the present disclosure are achieved to a certain degree, and reduction of a production load can also be implemented as a result of simplification of the number of processes.

Note that, in order to achieve the effects according to the present disclosure to the maximum, it is desirable that the feedforward be executed and the implantation amount and the implantation energy be determined so as to maintain the design center value α₀ with the absolute value being smaller than 1, regarding the charge balance amount α defined in expression (6), irrespective of the impurity concentration unevenness of the drift layer 20, resultant unevenness of the implantation mask, and the unevenness of the film thickness of the multi-epitaxial layer.

However, in order to achieve minimum effects, the unevenness of the charge balance amount α is reduced to or less than the average unevenness of the impurity concentration of the drift layer 20 per wafer within the wafer surface being the main cause of the unevenness. With this, the reduction of the breakdown voltage caused by the unevenness of the charge balance amount α due to the unevenness of the impurity concentration of the drift layer 20 can be further reduced than a case without feedforward, and minimum effects according to the present disclosure can be achieved.

### Second Embodiment

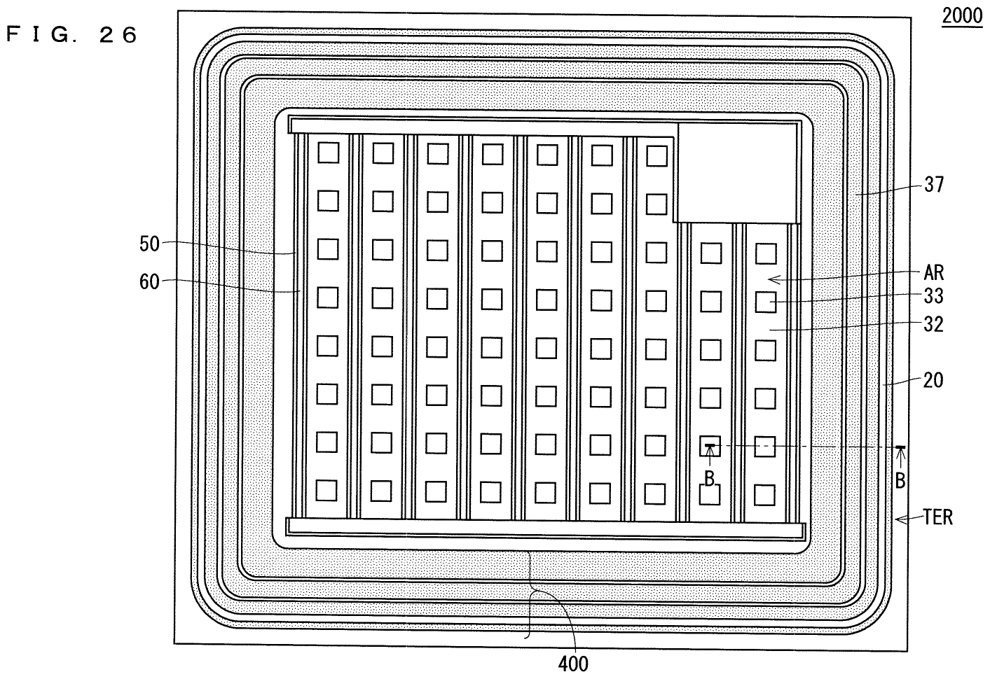

FIG. 26 is a plan view of the SJ-SiC-MOSFET 2000 according to the second embodiment in a state in which the source electrode 80, the gate pad 81, and the gate wiring 82 are removed from the plan view illustrated in FIG. 1.

In the second embodiment, a breakdown voltage termination structure at an outer peripheral portion is formed on the same condition as the implantation condition of the pillar region 30.

First, structures of a guard ring (GR) being the breakdown voltage termination structure used for an SiC power device and a field limiting ring (FLR) formed in combination of a plurality of the guard rings will be described.

FIG. 26 illustrates an active region AR, and a termination region TER provided at the outer periphery of the active region AR. In the active region AR, the body region 32, the gate insulation film 50, the gate electrode 60, and the body contact region 33 are illustrated, and in the termination region TER, an FLR region 400 is illustrated. Note that these are in plan view of a general trench MOSFET, and description thereof will be omitted.

Further, in the FLR region 400, a plurality of GRs 37 are concentrically provided. The GRs 37 illustrated in FIG. 26 are each a p-type region having impurity concentration lower than that of the body region 32, and are formed at intervals in the FLR region 400. In the FLR region 400, the GRs 37 are provided such that the ratio of the area occupied by the GRs 37 is reduced toward the outer peripheral direction.

The plurality of GRs 37 disposed as described above constitute an FLR structure. In a macroscopic view, the FLR structure is such a structure that average impurity concentration of the p-type impurity region is further reduced toward the outer peripheral direction, and has effects of enabling smooth electric field distribution and maintaining the breakdown voltage with a small termination region width in the termination region TER, on which the electric fields concentrate.

In contrast, in a design of the FLR as well, when there is unevenness in the epitaxial concentration, distribution of the impurity concentration of the termination region TER in a macroscopic view changes. For example, when the epitaxial concentration is increased, the ratio of n-type impurities in a region outside the FLR is increased, and thus the position with the maximum electric field intensity shifts toward a central side of a chip, whereas when the epitaxial concentration is reduced, the point with the maximum electric field intensity shifts toward an outer peripheral side of the chip. With these being taken into consideration, in comparison to a case without the unevenness of the epitaxial concentration, a large FLR width is generally designed.

In the second embodiment, the manufacturing process of the FLR is formed in the same process as the pillar region 30. In other words, feeding information of the epitaxial concentration and the film thickness of the epitaxial layer forward to the implantation process of the GRs 37 brings effects that the unevenness of the epitaxial concentration can be minimized in the termination region TER as well, the breakdown voltage of the active region AR can be increased, the width of the FLR region 400 of the termination region TER can be reduced, and chip costs can be reduced.

This is because a mechanism for reducing the electric field in the FLR region 400 is highly dependent upon a relative relationship between the impurity concentration of the drift layer 20 and the implantation region, as with the case of the pillar region 30. Further, the process of forming the FLR region 400 and the process of forming the pillar region 30 can be performed together, and accordingly the number of processes and process costs can be reduced.

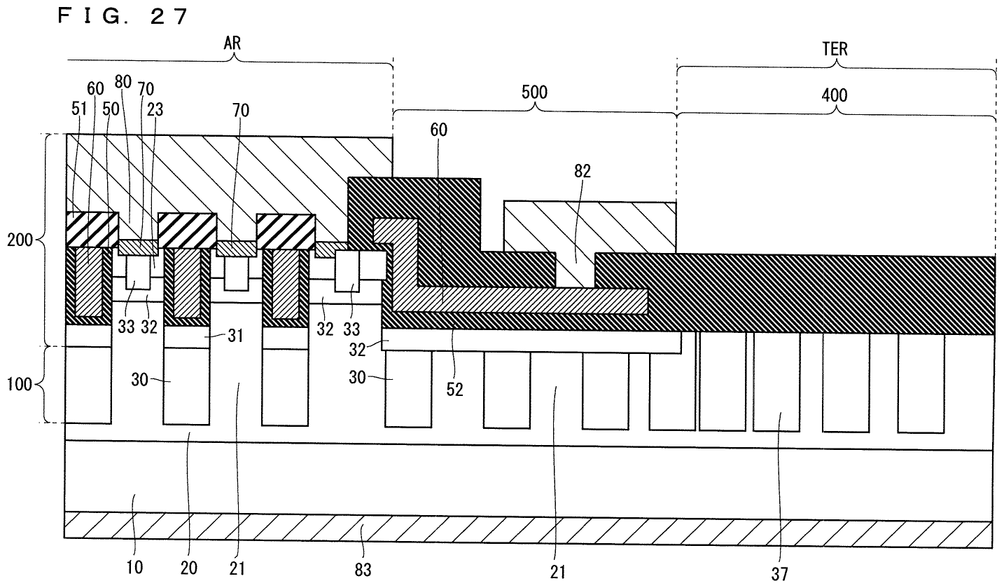

A cross-sectional diagram taken along the line B-B illustrated in FIG. 26, that is, the line B-B illustrated in FIG. 1, as seen in the direction of the arrows is illustrated in FIG. 27. Basically, the active region AR has a structure in which the unit cell illustrated in FIG. 2 is periodically repeated. In an outer peripheral region 500 between the active region AR and the FLR region 400, the body region 32 is formed to extend, and protects the gate electrode 60 in the outer peripheral region 500 and the gate wiring 82 above the gate electrode 60 from electric fields of the drift layer 20.

Further, a field insulation film 52 is provided below the gate electrode 60 made of polycrystalline silicon. When only a thin gate insulation film is provided below the gate electrode 60 having a large area in the outer peripheral region 500, an electric field stress may be applied to the gate insulation film due to variation of a drain voltage at the time of switching operation, and thus reliability is enhanced by providing a thick field insulation film 52 together with the gate insulation film.

Further, below the outer peripheral region 500, the pillar region 30 and the pillar region 21 are provided with a period similar to that of the active region AR to constitute the SJ region 100, and electric field distribution and the breakdown voltage in the vertical direction are thereby secured.

In the FLR region 400, a plurality of GRs 37 formed with the same implantation mask as that used to form the pillar region 30 and in the same implantation process are formed such that disposition intervals thereof are increased toward the outer side.

### Third Embodiment

Although the first embodiment and the second embodiment describe a trench MOSFET, the manufacturing method of the present disclosure can also be applied to a planar MOSFET.

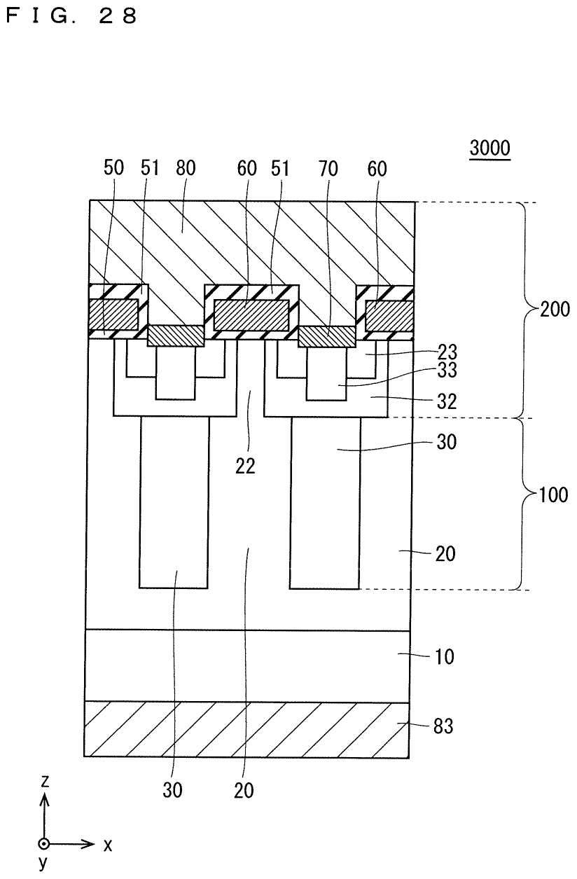

FIG. 28 is a cross-sectional diagram illustrating a configuration of a unit cell of a planar SJ-SiC-MOSFET 3000 of a third embodiment. As illustrated in FIG. 28, in the SJ-SiC-MOSFET 3000, the n-type drift layer 20 is provided on the first main surface of the n-type silicon carbide semiconductor substrate 10. In the drift layer 20, the p-type pillar region 30 formed with an ion implantation method and activation annealing is provided. Further, an n-type region in the drift layer 20 in which the pillar region 30 is not formed is referred to as the pillar region 21.

As illustrated in FIG. 28, a region in which the pillar region 21 and the pillar region 30 are repeatedly arrayed in the horizontal direction in the drawing sheet, that is, an array direction (x direction) of the gate electrodes 60, is referred to as the SJ region 100, which is the same as the first embodiment. In the SJ region 100, the pillar region 21 and the pillar region 30 are formed along the depth direction in the drawing sheet in plan view, that is, in an extension direction (y direction) of each gate electrode 60, and is formed to have a stripe shape in plan view.

Further, a region above the SJ region 100 is referred to as the MOSFET region 200, and the pillar region 30 is connected to a p-type impurity region in the MOSFET region 200.

In the MOSFET region 200, the p-type body region 32 is selectively provided in an upper layer portion of the drift layer 20, and the n-type source region 23 is provided within the surface of the body region 3. Inside the source region 23 and the body region 32, the p-type body contact region 33 is provided. The body contact region 33 is provided to penetrate the source region 23 but not to penetrate the body region 32.

The gate insulation film 50 made of silicon oxide or the like is provided on the drift layer 20 to extend across adjacent source regions 23, and the gate electrodes 60 made of polycrystalline silicon or the like are provided on the gate insulation film 50. Each gate electrode 60 is covered by the interlayer insulation film 51 made of silicon oxide.

The ohmic electrode 70 is provided above the body contact region 33, and the ohmic electrode 70 is connected to the source electrode 80 through an opening provided between the interlayer insulation films 51.

An n-type region below the gate insulation film 50 and between adjacent body regions 32 corresponds to the JFET region 22. Since impurity concentration of the JFET region 22 is not required to have a charge balance, unlike that of the SJ region 100, the impurity concentration may be higher than that of the pillar region 21, so that JFET resistance is reduced.

When the planar MOSFET is employed, the trench etching process and the formation process of the electric field protection region 31 below the trenches can be omitted, and thus the number of processes can be reduced. Basically, the formation process of the SJ region 100 does not differ from that of the first embodiment. Further, as an additional constituent element, the JFET region 22 formed between adjacent body regions 32 is present.

The JFET region 22 may have further reduced on-resistance by increasing the impurity concentration higher than that of the drift layer 20 and the pillar region 21 through the epitaxial process or the ion implantation process. In contrast, to omit a cleaning process, the JFET region 22 may have the same impurity concentration as that of the drift layer 20 or the pillar region 21.

Note that it is desirable that the pillar region 30 be provided below the center of the body region 32 periodically and repeatedly disposed. This does not easily obstruct a current path in the ON state, that is, a path of the main current flowing from the drain electrode 83 to the source electrode 80 through the silicon carbide semiconductor substrate 10, the drift layer 20, the pillar region 21, the JFET region 22, and the source region 23, and thus the effects according to the SJ structure can be achieved to the maximum.

### Modification

As a modification of the third embodiment, in the planar SJ-SiC-MOSFET 3000 as well, similarly to the second embodiment, the breakdown voltage termination structure at an outer peripheral portion can be formed on the same condition as the implantation condition of the pillar region 30.

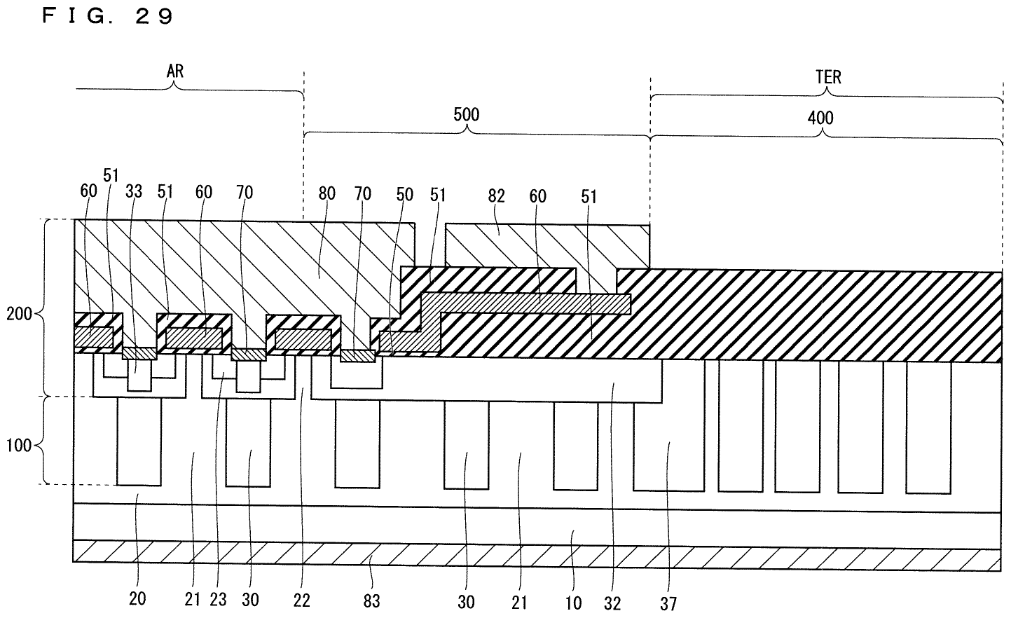

A cross-sectional diagram corresponding to FIG. 27 of the second embodiment is illustrated in FIG. 29. Basically, the active region AR has a structure in which the unit cell illustrated in FIG. 28 is periodically repeated. In the outer peripheral region 500 between the active region AR and the FLR region 400, the body region 32 is formed to extend, and protects the gate electrode 60 in the outer peripheral region 500 and the gate wiring 82 above the gate electrode 60 from electric fields of the drift layer 20.

In the FLR region 400, a plurality of GRs 37 formed with the same implantation mask as that used to form the pillar region 30 and in the same implantation process are formed such that disposition intervals thereof are increased toward the outer side.

By forming the manufacturing process of the FLR in the same process as the pillar region 30, information of the epitaxial concentration and the film thickness of the epitaxial layer is fed forward to the implantation process of the GRs 37, and the unevenness of the epitaxial concentration can be minimized in the termination region TER as well. With this, the effect of optimization of the charge imbalance in the active region AR can be achieved, and also the effect that the width of the FLR region 400 can be reduced through reduction of the unevenness of the electric field distribution in the termination region TER can be achieved. Note that the SJ region 100 is formed below the outer peripheral region 500, as with below the active region AR.

Note that, in the present disclosure, each of the embodiments can be freely combined and each of the embodiments can be modified or omitted as appropriate within the scope of the disclosure.

The present disclosure described above is summarized as appendixes.

### Appendix 1

A manufacturing method for a silicon carbide semiconductor device, the manufacturing method including the steps of:
(a) forming a drift layer of a first conductivity type on a silicon carbide semiconductor substrate of the first conductivity type through epitaxial growth;
(b) measuring impurity concentration of the drift layer;
(c) forming an ion implantation mask on the drift layer, the ion implantation mask including a plurality of first openings being periodically provided;
(d) implanting impurity ions of a second conductivity type through the plurality of first openings, forming a plurality of second pillar regions of the second conductivity type in the drift layer, and turning the drift layer between the plurality of second pillar regions into a first pillar region of the first conductivity type;
(e) forming an epitaxial layer of the first conductivity type on the drift layer through epitaxial growth; and
(f) forming a plurality of unit cells of a transistor in the epitaxial layer, wherein
the step (d) includes performing feedforward control on an ion implantation amount of the impurity ions so that there is a positive correlation with measurement results of the step (b).

### Appendix 2

The manufacturing method for the silicon carbide semiconductor device according to Appendix 1, further including
(g) measuring film thickness of the drift layer, between the step (b) and the step (c), wherein
the step (d) further includes performing feedforward control on ion implantation energy for the impurity ions so that there is a positive correlation with measurement results of the step (g).

### Appendix 3

A manufacturing method for a silicon carbide semiconductor device, the manufacturing method including the steps of:
(a) forming a drift layer of a first conductivity type on a silicon carbide semiconductor substrate of the first conductivity type through epitaxial growth;
(b) measuring film thickness of the drift layer;
(c) forming an ion implantation mask on the drift layer, the ion implantation mask including a plurality of first openings being periodically provided;
(d) implanting impurity ions of a second conductivity type through the plurality of first openings, forming a plurality of second pillar regions of the second conductivity type in the drift layer, and turning the drift layer between the plurality of second pillar regions into a first pillar region of the first conductivity type;
(e) forming an epitaxial layer of the first conductivity type on the drift layer through epitaxial growth; and
(f) forming a plurality of unit cells of a transistor in the epitaxial layer, wherein
the step (d) includes performing feedforward control on ion implantation energy for the impurity ions so that there is a positive correlation with measurement results of the step (b).

### Appendix 4

The manufacturing method for the silicon carbide semiconductor device according to Appendix 3, further including
(g) measuring impurity concentration of the drift layer, between the step (b) and the step (c), wherein
the step (d) further includes performing feedforward control on an ion implantation amount of the impurity ions so that there is a positive correlation with measurement results of the step (g).

### Appendix 5

The manufacturing method for the silicon carbide semiconductor device according to Appendix 1 or 4, further including
(h) measuring average opening width of the plurality of first openings of the ion implantation mask, between the step (c) and the step (d), wherein
the step (d) further includes performing feedforward control on the ion implantation amount so that there is a negative correlation with measurement results of the step (h).

### Appendix 6

The manufacturing method for the silicon carbide semiconductor device according to Appendix 1 or 4, wherein
in the step (d), ion implantation of the impurity ions is performed, with an implantation condition of at least Level 2 being set for width of unevenness of the impurity concentration of the drift layer.

### Appendix 7

The manufacturing method for the silicon carbide semiconductor device according to Appendix 1 or 3, wherein
in the step (c), the ion implantation mask is formed so as to form a plurality of second openings for forming a plurality of guard rings at an outer peripheral portion of the silicon carbide semiconductor substrate, and
in the step (d), the impurity ions of the second conductivity type are implanted through the plurality of second openings, and the plurality of guard rings are formed at the outer peripheral portion in an implantation profile same as the implantation profile of the plurality of second pillar regions.

### Appendix 8

The manufacturing method for the silicon carbide semiconductor device according to Appendix 1 or 3, wherein
the transistor is a trench transistor including a trench gate being provided in the epitaxial layer,
the step (f) includes forming an electric field protection region of the second conductivity type at a bottom portion of the trench gate, the electric field protection region having concentration higher than the concentration of the plurality of second pillar regions, and
the electric field protection region is connected to the plurality of second pillar regions.

### Appendix 9

The manufacturing method for the silicon carbide semiconductor device according to Appendix 1 or 3, wherein
the transistor is a planar transistor including a gate being provided on the epitaxial layer,
the step (f) includes forming a body region of the second conductivity type at an upper layer portion of the epitaxial layer, the body region having concentration higher than the concentration of the plurality of second pillar regions, and
the body region is connected to the plurality of second pillar regions.

While the disclosure has been shown and described in detail, the foregoing description is in all aspects illustrative and not restrictive. It is therefore understood that numerous modifications and variations can be devised.

What is claimed is:

1. A manufacturing method for a silicon carbide semiconductor device, the manufacturing method comprising the steps of:
(a) forming a drift layer of a first conductivity type on a silicon carbide semiconductor substrate of the first conductivity type through epitaxial growth;
(b) measuring impurity concentration of the drift layer;
(c) forming an ion implantation mask on the drift layer, the ion implantation mask including a plurality of first openings being periodically provided;
(d) implanting impurity ions of a second conductivity type through the plurality of first openings, forming a plurality of second pillar regions of the second conductivity type in the drift layer, and turning the drift layer between the plurality of second pillar regions into a first pillar region of the first conductivity type;
(e) forming an epitaxial layer of the first conductivity type on the drift layer through epitaxial growth; and
(f) forming a plurality of unit cells of a transistor in the epitaxial layer, wherein
the step (d) comprises performing feedforward control on an ion implantation amount of the impurity ions so that there is a positive correlation with measurement results of the step (b).

2. The manufacturing method for the silicon carbide semiconductor device according to claim 1, further comprising
(g) measuring film thickness of the drift layer, between the step (b) and the step (c), wherein
the step (d) further comprises performing feedforward control on ion implantation energy for the impurity ions so that there is a positive correlation with measurement results of the step (g).

3. The manufacturing method for the silicon carbide semiconductor device according to claim 1, further comprising
(h) measuring average opening width of the plurality of first openings of the ion implantation mask, between the step (c) and the step (d), wherein
the step (d) further comprises performing feedforward control on the ion implantation amount so that there is a negative correlation with measurement results of the step (h).

4. The manufacturing method for the silicon carbide semiconductor device according to claim 1, wherein
in the step (d), ion implantation of the impurity ions is performed, with an implantation condition of at least Level 2 being set for width of unevenness of the impurity concentration of the drift layer.

5. The manufacturing method for the silicon carbide semiconductor device according to claim 1, wherein
in the step (c), the ion implantation mask is formed so as to form a plurality of second openings for forming a plurality of guard rings at an outer peripheral portion of the silicon carbide semiconductor substrate, and
in the step (d), the impurity ions of the second conductivity type are implanted through the plurality of second openings, and the plurality of guard rings are formed at the outer peripheral portion in an implantation profile same as the implantation profile of the plurality of second pillar regions.

6. The manufacturing method for the silicon carbide semiconductor device according to claim 1, wherein
the transistor is a trench transistor including a trench gate being provided in the epitaxial layer,
the step (f) comprises forming an electric field protection region of the second conductivity type at a bottom portion of the trench gate, the electric field protection region having concentration higher than the concentration of the plurality of second pillar regions, and
the electric field protection region is connected to the plurality of second pillar regions.

7. The manufacturing method for the silicon carbide semiconductor device according to claim 1, wherein
the transistor is a planar transistor including a gate being provided on the epitaxial layer,
the step (f) comprises forming a body region of the second conductivity type at an upper layer portion of the epitaxial layer, the body region having concentration higher than the concentration of the plurality of second pillar regions, and
the body region is connected to the plurality of second pillar regions.

8. A manufacturing method for a silicon carbide semiconductor device, the manufacturing method comprising the steps of:
(a) forming a drift layer of a first conductivity type on a silicon carbide semiconductor substrate of the first conductivity type through epitaxial growth;
(b) measuring film thickness of the drift layer;
(c) forming an ion implantation mask on the drift layer, the ion implantation mask including a plurality of first openings being periodically provided;
(d) implanting impurity ions of a second conductivity type through the plurality of first openings, forming a plurality of second pillar regions of the second conductivity type in the drift layer, and turning the drift layer between the plurality of second pillar regions into a first pillar region of the first conductivity type;
(e) forming an epitaxial layer of the first conductivity type on the drift layer through epitaxial growth; and
(f) forming a plurality of unit cells of a transistor in the epitaxial layer, wherein
the step (d) comprises performing feedforward control on ion implantation energy for the impurity ions so that there is a positive correlation with measurement results of the step (b).

9. The manufacturing method for the silicon carbide semiconductor device according to claim 8, further comprising
(g) measuring impurity concentration of the drift layer, between the step (b) and the step (c), wherein
the step (d) further comprises performing feedforward control on an ion implantation amount of the impurity ions so that there is a positive correlation with measurement results of the step (g).

10. The manufacturing method for the silicon carbide semiconductor device according to claim 9, further comprising
(h) measuring average opening width of the plurality of first openings of the ion implantation mask, between the step (c) and the step (d), wherein
the step (d) further comprises performing feedforward control on the ion implantation amount so that there is a negative correlation with measurement results of the step (h).

11. The manufacturing method for the silicon carbide semiconductor device according to claim 9, wherein
in the step (d), ion implantation of the impurity ions is performed, with an implantation condition of at least Level 2 being set for width of unevenness of the impurity concentration of the drift layer.

12. The manufacturing method for the silicon carbide semiconductor device according to claim 8, wherein
in the step (c), the ion implantation mask is formed so as to form a plurality of second openings for forming a plurality of guard rings at an outer peripheral portion of the silicon carbide semiconductor substrate, and
in the step (d), the impurity ions of the second conductivity type are implanted through the plurality of second openings, and the plurality of guard rings are formed at the outer peripheral portion in an implantation profile same as the implantation profile of the plurality of second pillar regions.

13. The manufacturing method for the silicon carbide semiconductor device according to claim 8, wherein
the transistor is a trench transistor including a trench gate being provided in the epitaxial layer,
the step (f) comprises forming an electric field protection region of the second conductivity type at a bottom portion of the trench gate, the electric field protection region having concentration higher than the concentration of the plurality of second pillar regions, and
the electric field protection region is connected to the plurality of second pillar regions.

14. The manufacturing method for the silicon carbide semiconductor device according to claim 8, wherein
the transistor is a planar transistor including a gate being provided on the epitaxial layer,
the step (f) comprises forming a body region of the second conductivity type at an upper layer portion of the epitaxial layer, the body region having concentration higher than the concentration of the plurality of second pillar regions, and
the body region is connected to the plurality of second pillar regions.
